(19) United States
(12) Patent Application Publication
(10) Pub. No.: US 2026/0333662 A1
(43) Pub. Date: Oct. 22, 2026

(54) SEMICONDUCTOR MEMORY DEVICE AND MANUFACTURING METHOD THEREOF

(71) Applicant: Samsung Electronics Co., Ltd., Suwon-si (KR)

(72) Inventors: Hyunjin Lee, Suwon-si (KR); Minju Kang, Suwon-si (KR); Sujin Kang, Suwon-si (KR); Minsoo Kim, Suwon-si (KR); Seunghoon Kim, Suwon-si (KR); Juho Lee, Suwon-si (KR); Inho Cha, Suwon-si (KR); Yongkwan Kim, Suwon-si (KR); Huijung Kim, Suwon-si (KR); Heejae Chae, Suwon-si (KR); Sungduk Hong, Suwon-si (KR)

(21) Appl. No.: 19/468,426

(22) Filed: Feb. 3, 2026

(30) Foreign Application Priority Data
Feb. 12, 2025 (KR) 10-2025-0018092

(51) Int. Cl. H10B 12/00

(52) U.S. Cl. CPC H10B 12/00

(57) ABSTRACT

A semiconductor memory device including memory cells arranged three-dimensionally on a substrate, each of memory cells including a first transistor including a first channel layer and a second transistor including a second channel layer located above and below the first channel layer, a bit line connected to one end portion of the first channel layer and extending in a vertical direction, a ground electrode connected to the other end portion of the first channel layer and extending in the vertical direction, a storage node located above and below the first channel layer while in contact with a first surface of the second channel layer, the second channel layer and the storage node surrounding the first channel layer between the bit line and the ground electrode, and a word line surrounding the storage node and the second channel layer between the bit line and the ground electrode.

### CROSS-REFERENCE TO RELATED APPLICATION(S)

This application is based on and claims priority under 35 USC § 119 to Korean Patent Application No. 10-2025-0018092, filed on Feb. 12, 2025, in the Korean Intellectual Property Office, the disclosure of which is incorporated by reference herein in its entirety.

### BACKGROUND

The present disclosure relates to a semiconductor memory device and manufacturing method thereof. Particularly, the present disclosure relates to a semiconductor memory device including a gate-all-around (GAA) structure and a manufacturing method thereof.

Due to the advancement of electronics technology, downscaling of semiconductor devices has progressed rapidly. Accordingly, miniaturization of memory cells has been required, and there may be limitations in maintaining high integration and reliability in existing memory cells. Therefore, research has been conducted to develop semiconductor memory devices with a structure that facilitates miniaturization and high integration of memory cells.

### SUMMARY

The present disclosure provides a semiconductor memory device that may be easily highly integrated.

The present disclosure also provides a method of manufacturing a semiconductor memory device that may be easily highly integrated.

The problems to be solved by the technical idea of the present disclosure are not limited to the problems mentioned above, and other problems may be clearly understood by those skilled in the art from the description below.

According to an aspect of the present disclosure, there is provided a semiconductor memory device including a plurality of memory cells arranged three-dimensionally on a substrate in a first horizontal direction, a second horizontal direction orthogonal to the first horizontal direction, and a vertical direction perpendicular to the first horizontal direction and the second horizontal direction, each of the plurality of memory cells including a first transistor including a first channel layer and a second transistor including a second channel layer located above and below the first channel layer, a bit line connected to one end portion of the first channel layer and extending in the vertical direction, a ground electrode connected to the other end portion of the first channel layer and extending in the vertical direction, a storage node located above and below the first channel layer while in contact with a first surface of the second channel layer, the second channel layer and the storage node surrounding the first channel layer between the bit line and the ground electrode, and a word line surrounding the storage node and the second channel layer between the bit line and the ground electrode.

According to another aspect of the present disclosure, there is provided a semiconductor memory device including a first channel layer extending in a second horizontal direction on a substrate and apart in a first horizontal direction perpendicular to the second horizontal direction, the first channel layer having a first surface and a second surface opposite to the first surface in the second horizontal direction, a second channel layer located above and below the first channel layer, the second channel layer having a first surface and a second surface opposite to the first surface in the second horizontal direction, a storage node disposed above and below the first channel layer while in contact with the first surface of the second channel layer and formed inwardly relative to the first surface of the first channel layer in the second horizontal direction, a bit line contacting one end portion of each of the first channel layer and the second channel layer in a vertical direction perpendicular to the first horizontal direction and the second horizontal direction, a ground electrode in contact with the other end portion of the first channel layer in the vertical direction, and a word line located above the second channel layer and the storage node between the bit line and the ground electrode, wherein the second channel layer and the storage node surround the first channel layer, and the word line surrounds the second channel layer and the storage node.

According to another aspect of the present disclosure, there is provided a semiconductor memory device including a first channel layer extending in a second horizontal direction on a substrate and apart in a first horizontal direction perpendicular to the second horizontal direction, the first channel layer having a first surface and a second surface opposite to the first surface in the second horizontal direction, a second channel layer located above and below the first channel layer, the second channel layer having a first surface and a second surface opposite to the first surface in the second horizontal direction, a storage node disposed above and below the first channel layer while in contact with the first surface of the second channel layer and formed inwardly relative to the first surface of the first channel layer in the second horizontal direction, a bit line contacting one end portion of each of the first channel layer and the second channel layer in a vertical direction perpendicular to the first horizontal direction and the second horizontal direction, a ground electrode in contact with the other end portion of the first channel layer in the vertical direction, a word line located above the second channel layer between the bit line and the ground electrode, the second channel layer and the storage node surrounding the first channel layer, and the word line surrounding the second channel layer without overlapping the storage node in the vertical direction, a first gate insulating layer located between the first channel layer and the storage node and between the first channel layer and the second channel layer, and a second gate insulating layer located between the second channel layer and the word line and between the storage node and the word line.

According to another aspect of the present disclosure, there is provided a method for manufacturing a semiconductor memory device including forming a first channel layer extending in a second horizontal direction on a substrate and apart in a first horizontal direction perpendicular to the second horizontal direction, the first channel layer having a first surface and a second surface opposite to the first surface in the second horizontal direction, forming a first gate insulating layer surrounding the first channel layer, forming a second channel layer having a first surface and a second surface opposite to the first surface in the second horizontal direction on the first gate insulating layer above and below the first channel layer, forming a storage node in contact with the first surface of the second channel layer and inwardly relative to the first surface of the first channel layer above and below the first channel layer in the second horizontal direction, forming a second gate insulating layer surrounding the second channel layer and the storage node, forming a word line extending in the first horizontal direction on the second gate insulating layer above and below the second channel layer and the storage node, forming a bit line in contact with one end portion of each of the first channel layer and the second channel layer in a vertical direction perpendicular to the first horizontal direction and the second horizontal direction, and forming a ground electrode in contact with the other end portion of the first channel layer in the vertical direction, wherein, in the first horizontal direction, the second channel layer and the storage node are formed to surround the first channel layer, and the word line is formed to surround the second channel layer.

In some implementations, the first channel layer include crystalline silicon. The second channel layer may include at least one of an oxide semiconductor, polysilicon, a 2D material semiconductor, or combinations thereof.

In some implementations, the word line may be formed to surround both the second channel layer and the storage node. The second surface of the second channel layer, which is opposite to the first surface, may be formed to be in contact with the bit line.

In some implementations, the first gate insulating layer may be formed between the first channel layer and the storage node and between the first channel layer and the second channel layer. The second gate insulating layer may be formed between the second channel layer and the word line and between the storage node and the word line.

In some implementations, a work function adjustment layer in contact with the word line may be further formed on the second channel layer on one side of the word line. A bit line-side channel doping region in contact with the bit line may be further formed at one end of the first channel layer. A ground-side channel doping region in contact with the ground electrode may be further formed at the other end of the first channel layer. A silicide layer in contact with the bit line or the ground electrode may be further formed at one end or the other end of the first channel layer.

### BRIEF DESCRIPTION OF THE DRAWINGS

Implementations will be more clearly understood from the following detailed description taken in conjunction with the accompanying drawings in which:

FIG. 1 is an equivalent circuit diagram illustrating a cell array of a semiconductor memory device according to some implementations;

FIGS. 2A, 2B, 2C, 2D, 2E, 2F, 2G to 2H are diagrams illustrating a semiconductor memory device according to some implementations;

FIG. 3 is a layout diagram illustrating a semiconductor memory device according to some implementations;

FIGS. 4A and 4B are cross-sectional views illustrating semiconductor memory devices according to implementations;

FIGS. 5A, 5B, and 5C are cross-sectional views illustrating semiconductor memory devices according to implementations;

FIGS. 6A, 6B, and 6C are cross-sectional views illustrating semiconductor memory devices according to implementations;

FIGS. 7A and 7B are cross-sectional views illustrating semiconductor memory devices according to implementations; and

FIGS. 8A, 8B, 8C, 8D, 8E, 9A, 9B, 9C, 9D, 9E, 10A, 10B, 10C, 10D, 10E, 11A, 11B, 11C, 11D, 11E, 12A, 12B, 12C, 12D, 12E, 13A, 13B, 13C, 13D, 13E, 14A, 14B, 14C, 14D, 14E, 15A, 15B, 15C, 15D, 15E, 16A, 16B, 16C, 16D, 16E, 16F, 17A, 17B, 17C, 17D, 17E, 17F, 18A, 18B, 18C, 18D, 18E, 18F, 19A, 19B, 19C, 19D, 19E, and 19F are diagrams illustrating a method of manufacturing a semiconductor memory device, according to some implementations.

### DETAILED DESCRIPTION

Hereinafter, implementations of the present disclosure are described in detail with reference to the accompanying drawings. The implementations of the present disclosure may be realized by a single implementation and may also be realized by a combination of more than one implementation. Therefore, the technical idea of the present disclosure should not be construed by one of the implementations.

Herein, the singular form of components may include the plural form unless the context clearly indicates otherwise. Herein, the drawings are exaggerated to more clearly describe the present disclosure.

Herein, the terms “first”, “second”, etc. are used to describe various elements or components, but it is to be understood that these elements or components are not limited by these terms. These terms are only used to distinguish one element or component from another. Therefore, a first element or first component mentioned below may also be a second element or second component within the technical concept of the present disclosure.

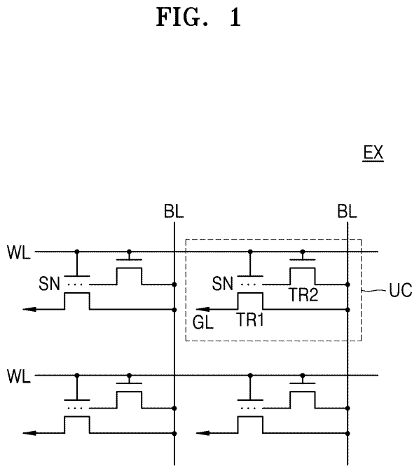

FIG. 1 is an equivalent circuit diagram illustrating a cell array of a semiconductor memory device EX according to some implementations.

In an example, the semiconductor memory device EX may include a plurality of unit cells UC. A unit cell UC may include a pair of transistors, for example, a first transistor TR1 and a second transistor TR2. In some implementations, each of the first transistor TR1 and the second transistor TR2 may include a field effect transistor (FET). In an example, the first transistor may be a PMOS transistor and the second transistor may be an NMOS transistor.

Each unit cell UC included in the semiconductor memory device EX may operate as a DRAM memory cell in which a write operation for storing information and a read operation for reading information are performed. The unit cell UC may store information in a storage node SN instead of a capacitor. The semiconductor memory device EX including the plurality of unit cells UC may be referred to as a DRAM memory device having a floating gate. The semiconductor memory device EX including the plurality of unit cells UC may operate as a nonvolatile semiconductor memory device.

A word line WL may be electrically connected to a gate electrode of each of the first transistor TR1 and the second transistor TR2 included in the plurality of unit cells UC. One end of a channel layer of the first transistor TR1 may be electrically coupled to a bit line BL, and the other end of the channel layer may be electrically coupled to a ground electrode GL. The ground electrode GL may be biased as needed.

One end of a channel layer of the second transistor TR2 may be electrically coupled to the storage node SN, and the other end of the channel layer may be electrically coupled to the bit line BL. The second transistor TR2 may store charge in the storage node SN.

Depending on the amount of charge stored in the storage node SN, a threshold voltage of the first transistor TR1 in which the storage node SN functions as a floating gate may change. The storage node SN may be a floating gate of the first transistor (TR1). Depending on the threshold voltage of the first transistor TR1, determined by the amount of charge stored in the storage node SN, information stored in the unit cell UC may be read as ‘0’ or ‘1’.

For example, the second transistor TR2 of one unit cell UC may be selected by one word line WL and one bit line BL and charge may be stored in a channel layer below the storage node SN. In addition, the first transistor TR1 of one unit cell UC may be selected by one word line WL and one bit line BL.

Information stored in the unit cell UC may be read according to the threshold voltage of the first transistor TR1, determined by the amount of charge stored in the channel layer below the storage node SN. The first transistor TR1 may be referred to as a read transistor, and the second transistor TR2 may be referred to as a write transistor. The unit cell UC may be named a 2T memory cell.

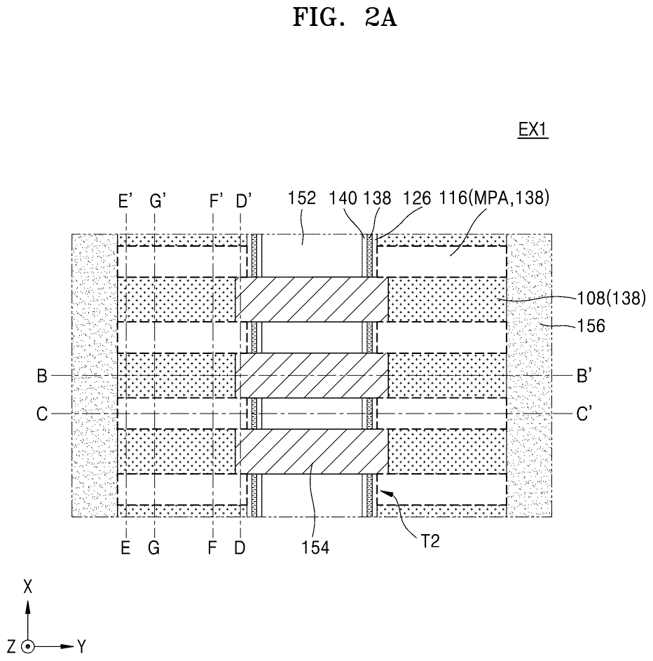

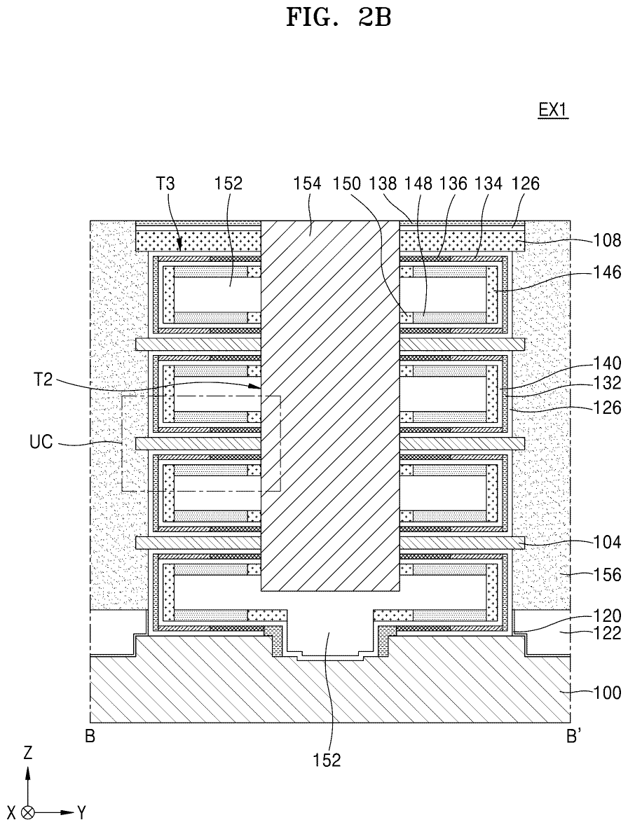

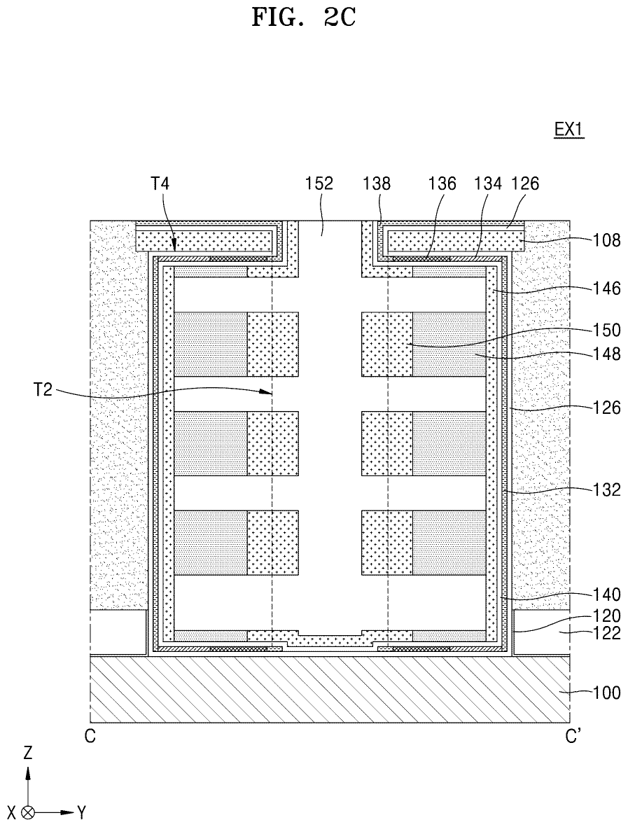

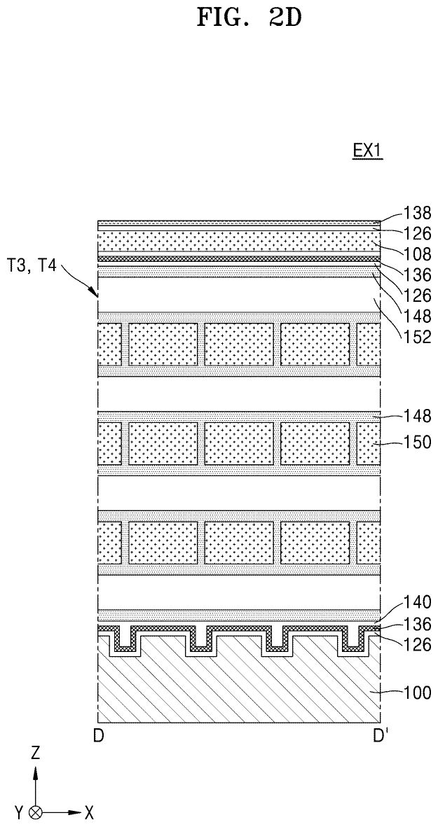

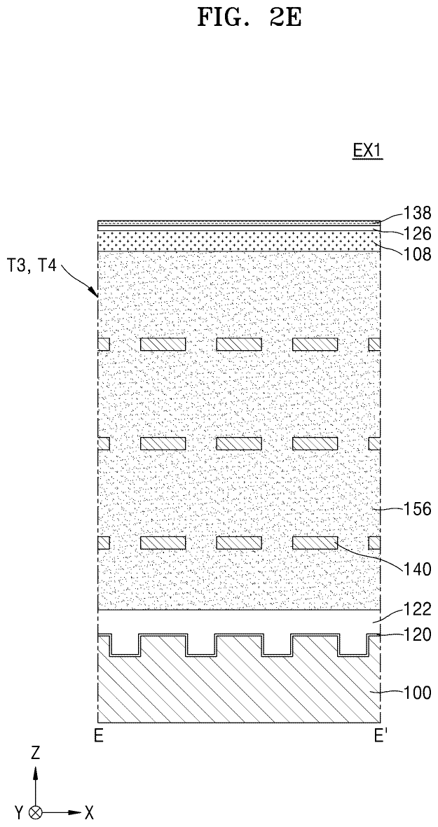

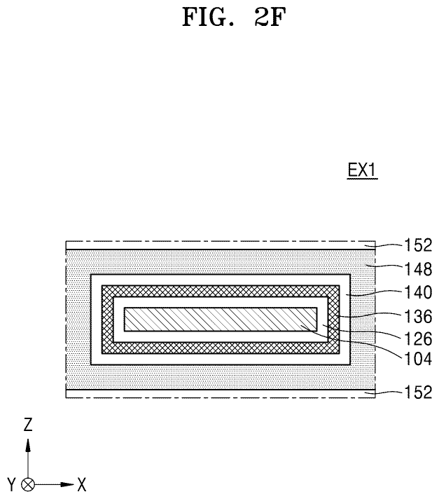

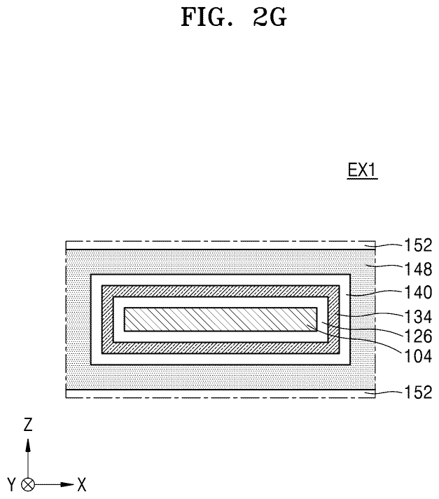

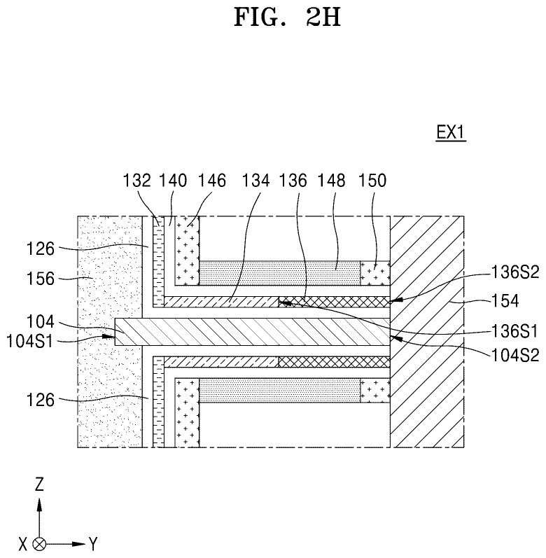

FIGS. 2A, 2B, 2C, 2D, 2E, 2F, 2G, and 2H are diagrams illustrating a semiconductor memory device EX1 according to some implementations.

Specifically, FIG. 2A is a layout diagram of the semiconductor memory device EX1. FIGS. 2B, 2C, 2D, 2E, 2F, and 2G are cross-sectional views taken along lines B-B′, C-C′, D-D′, E-E′, F-F′, and G-G′ of FIG. 2A, respectively. FIG. 2H is an enlarged cross-sectional view of a portion of FIG. 2B.

Referring to FIG. 2A, the semiconductor memory device EX1 may include a mold pattern MPA, a mold cover layer 108, a bit line 154, and a ground electrode 156 in the layout. The bit line 154 may correspond to the bit line BL of FIG. 1, and the ground electrode 156 may correspond to the ground electrode GL of FIG. 1. A bias voltage may be applied to the ground electrode 156 as needed.

The mold patterns MPA may be arranged apart in a first horizontal direction (an X direction) and a second horizontal direction (a Y direction). The mold pattern MPA may be configured as a second mold layer 116. The mold cover layer 108 may be placed between the mold patterns MPA. A first capping insulating layer 138 may be placed on the mold cover layer 108 and the mold pattern MPA in a manufacturing process.

The bit line 154 is arranged in a second trench T2 inside the mold cover layer 108 in the layout. The bit lines 154 extend in the second horizontal direction (the Y direction) and are apart from each other in the first horizontal direction (the X direction). The ground electrode 156 may be arranged to extend in the first horizontal direction (the X direction) outside the mold cover layer 108.

A first gate insulating layer 126, a first capping insulating layer 138, and a second gate insulating layer 140 may be arranged on one sidewall of the second trench T2 in the manufacturing process. The second trench T2 may be filled with a fifth buried insulating layer 152.

Referring to FIGS. 2B and 2H, the semiconductor memory device EX1 may include a unit cell UC as illustrated in FIG. 2B. The unit cell UC of FIG. 2B may include the unit cell UC of FIG. 1. FIG. 2H may be an enlarged cross-sectional view of the unit cell UC of FIG. 2B.

The unit cell UC may be insulated by the fifth buried insulating layer 152 in the vertical direction (the Z direction) depending on the manufacturing process. The fifth buried insulating layer 152 may be formed inside a third trench T3 according to the manufacturing process. The third trench T3 may be a recessed trench extending inwardly from one side of the mold cover layer 108.

The unit cell UC of the semiconductor memory device EX1 may be a memory cell. The memory cell may be provided in plurality, and the plurality of memory cells may be arranged three-dimensionally on a substrate 100 in the first horizontal direction (the X direction), the second horizontal direction (the Y direction) orthogonal to the first horizontal direction (the X direction), and a vertical direction (a Z direction) perpendicular to the first horizontal direction (the X direction) and the second horizontal direction (the Y direction).

The memory cell may include a first channel layer 104, a storage node 134, a second channel layer 136, a first gate insulating layer 126, a second gate insulating layer 140, a bit line 154, a ground electrode 156, and a word line 148. The first channel layer 104 may extend in the second horizontal direction (the Y direction) on the substrate 100 and be apart in the first horizontal direction perpendicular to the second horizontal direction (the Y direction). The first channel layer 104 may have a first surface 104S1 in the second horizontal direction (the Y direction) and a second surface 104S2 opposite to the first surface 104S1.

The second channel layer 136 may be located above the first channel layer 104. The second channel layer 136 may have a first surface 136S1 in the second horizontal direction (the Y direction) and a second surface 136S2 opposite to the first surface 136S1.

The storage node 134 may be placed above and below the first channel layer 104, while in contact with the first surface 136S1 of the second channel layer 136. The storage node 134 may be formed inwardly relative to the first surface 104S1 of the first channel layer 104 in the second horizontal direction (the Y direction). The first channel layer 104 may protrude relative to one side of the storage node 134 in the second horizontal direction (the Y direction).

The bit line 154 may extend in the vertical direction (the Z direction) perpendicular to the first horizontal direction (the X direction) and the second horizontal direction (the Y direction). The bit line 154 may be placed inside the second trench T2 in the manufacturing process. The first gate insulating layer 126 and the first capping insulating layer 138 may remain on the mold cover layer 108 in the manufacturing process. The fifth buried insulating layer 152 may remain below the second trench T2.

The bit line 154 may contact one end portion of the first channel layer 104 and the second channel layer 136 in the vertical direction (the Z direction). The bit line 154 may contact the second surface 104S2 of the first channel layer 104 and the second surface 136S2 of the second channel layer 136 in the vertical direction (the Z direction).

The ground electrode 156 may extend in the vertical direction (the Z direction). The ground electrode 156 may be in contact with the other end portion of the first channel layer 104 in the vertical direction (the Z direction). The ground electrode 156 may be in contact with the first surface 104S1 of the first channel layer 104 in the vertical direction (the Z direction). A second buried insulating layer 122 and a third liner layer 120 may remain below the ground electrode 156 in the manufacturing process. A bias voltage may be applied to the ground electrode 156 as needed.

The word line 148 may be located above and below the second channel layer 136 and the storage node 134 between the bit line 154 and the ground electrode 156. The word line 148 may extend in the first horizontal direction (the X direction) to surround at least a portion of each of the second channel layer 136 and the storage node 134. The word line 148 may also be placed between adjacent unit cells, as well as above and below the second channel layer 136 and the storage node 134, as illustrated in FIG. 2D below.

The first gate insulating layer 126 may be located between the first channel layer 104 and the storage node 134 and between the first channel layer 104 and the second channel layer 136. The second gate insulating layer 140 may be located between the second channel layer 136 and the word line 148 and between the storage node 134 and the word line 148.

The first channel layer 104, the first gate insulating layer 126, the second gate insulating layer 140, and the word line 148 may constitute the first transistor TR1 of FIG. 1. The second channel layer 136, the first gate insulating layer 126, the second gate insulating layer 140, and the word line 148 may constitute the second transistor TR2 of FIG. 1.

Between the bit line 154 and the word line 148, a second capping insulating pattern 150 may be arranged in the second horizontal direction (the Y direction) according to the manufacturing process. Between the ground electrode 156 and the word line 148, a fourth liner pattern 132 and a fifth liner pattern 146 may be formed in the second horizontal direction (the Y direction) according to the manufacturing process.

Referring to FIG. 2C, the semiconductor memory device EX1 may include the second trench T2 and a fourth trench T4 recessed inwardly from one surface of the mold cover layer 108 according to the manufacturing process. The first gate insulating layer 126 and the first capping insulating layer 138 may be arranged on the mold cover layer 108 according to the manufacturing process.

The semiconductor memory device EX1 may include the second buried insulating layer 122, the second gate insulating layer 140, the first gate insulating layer 126, the fifth liner pattern 146, the word line 148, the second capping insulating pattern 150, and the fifth buried insulating layer 152.

The word lines 148 may be located apart from each other within the fourth trench T4 in the vertical direction. The fifth liner pattern 146, the second gate insulating layer 140, the fourth liner pattern 132, and the first gate insulating layer 126 may be located on one sidewall of the word line 148. The second capping insulating pattern 150 may be located on the other sidewall of the word line 148. The storage node 134 and the second channel layer 136 may be formed above and below the second trench T2 and the fourth trench T4 in the manufacturing process.

Referring to FIG. 2D, the semiconductor memory device EX1 may include a third trench T3 and the fourth trench T4. The first gate insulating layer 126 and the first capping insulating layer 138 are formed on the mold cover layer 108 in the manufacturing process.

The word line 148 is formed within the third trench T3 and the fourth trench T4. The word lines 148 extend in the first horizontal direction (the X direction) and are connected to each other in the vertical direction (the Z direction). The word line 148 may be formed in a shape that surrounds the first channel layer (104 in FIG. 2B).

The second capping insulating pattern 150 is arranged between word lines 148 in the first horizontal direction (the X direction). The fifth buried insulating layer 152 is formed between the word lines 148 in the vertical direction (the Z direction).

An uneven structure may be formed on the substrate 100 in the manufacturing process. The first gate insulating layer 126, the second channel layer 136, and the second gate insulating layer 140 may be formed on the substrate 100 having the uneven structure.

Referring to FIG. 2E, the semiconductor memory device EX1 may include the third trench T3 and the fourth trench T4. The first gate insulating layer 126 and the first capping insulating layer 138 are formed on the mold cover layer 108 in the manufacturing process.

The first channel layer 104 may be located within the third trench T3 and the fourth trench T4. The ground electrode 156 may be located in contact with the first channel layer 104.

Referring to FIG. 2F, the first gate insulating layer 126 may be formed to surround the first channel layer 104 in the vertical direction (the Z direction). The second channel layer 136 may be formed to surround the first gate insulating layer 126. The second gate insulating layer 140 may be formed to surround the second channel layer 136. The word line 148 may be formed to surround the second gate insulating layer 140. The fifth buried insulating layer 152 may be formed above and below the word line 148.

Referring to FIG. 2G, the first gate insulating layer 126 may be formed to surround the first channel layer 104 in the vertical direction (the Z direction). The storage node 134 may be formed to surround the first gate insulating layer 126. The second gate insulating layer 140 may be formed to surround the storage node 134. The word line 148 may be formed to surround the second gate insulating layer 140. The fifth buried insulating layer 152 may be formed above and below the word line 148.

In the semiconductor memory device EX1 of the present disclosure configured as described above, the second channel layer 136 and the storage node 134 are formed to surround the first channel layer 104 in the first horizontal direction (the X direction), and the word line 148 is configured to surround the second channel layer 136. The semiconductor memory device EX1 configured in this manner is advantageous for high integration and may also improve electrical characteristics.

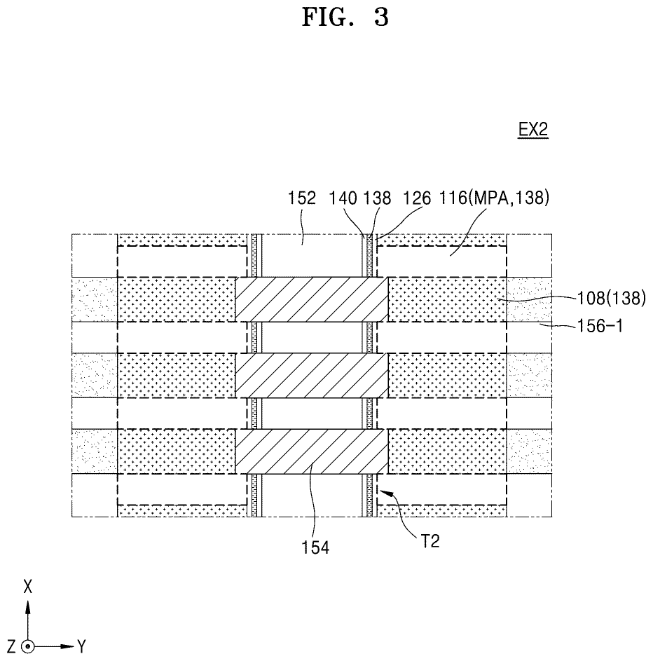

FIG. 3 is a layout diagram illustrating a semiconductor memory device EX2 according to some implementations.

In detail, the semiconductor memory device EX2 may be the same as the semiconductor memory device EX1 of FIG. 2A, except that a ground electrode 156-1 is separated. In FIG. 3, like reference numerals as those in FIG. 2A represent like members. In FIG. 3, the same descriptions as those given above with reference to FIG. 2A are briefly given or omitted.

The semiconductor memory device EX2 may include the mold pattern MPA, the mold cover layer 108, the bit line 154, and the ground electrode 156-1. The mold patterns MPA may be apart from each other in the first horizontal direction (the X direction) and the second horizontal direction (the Y direction).

The mold pattern MPA may be configured as a second mold layer 116. The mold cover layer 108 may be placed between the mold patterns MPA. The first capping insulating layer 138 may be placed on the mold cover layer 108 and the mold pattern MPA in the manufacturing process.

The bit line 154 is arranged within the second trench T2 inside the mold cover layer 108 in the layout. The bit lines 154 extend in the second horizontal direction (the Y direction) and are apart from each other in the first horizontal direction (the X direction).

The ground electrode 156-1 may be separated and placed outside the mold cover layer 108 in the first horizontal direction (the X direction). The ground electrode 156-1 may be arranged separately corresponding to the bit line 154.

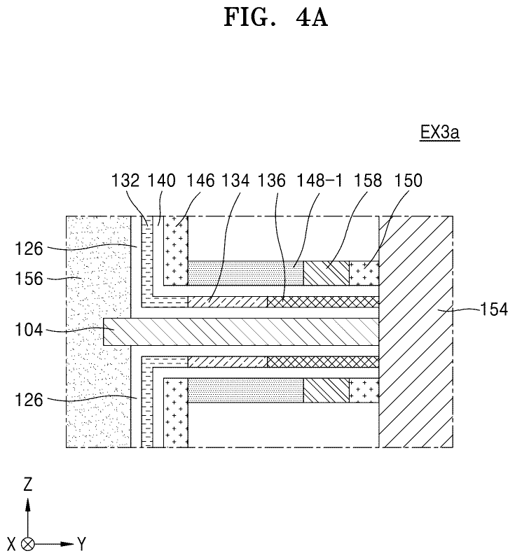

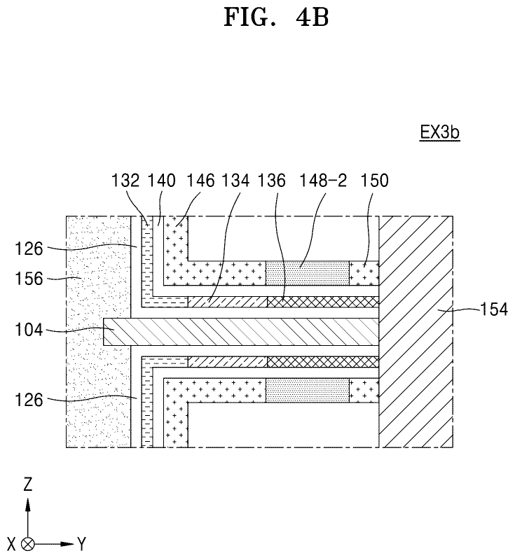

FIGS. 4A and 4B are cross-sectional views illustrating semiconductor memory devices EX3a and EX3b according to implementations.

In detail, the semiconductor memory device EX3a of FIG. 4A may be the same as the semiconductor memory device EX1 of FIG. 2H, except that the semiconductor memory device EX3a further includes a work function adjustment layer 158 on one side of a word line 148-1. A semiconductor memory device EX3b of FIG. 4B may be the same as the semiconductor memory device EX1 of FIG. 2H, except that a word line 148-2 does not overlap the storage node 134 in the vertical direction (the Z direction).

In FIGS. 4A and 4B, like reference numerals as those in FIG. 2H represent like members. In FIGS. 4A and 4B, the same descriptions as those given above with reference to FIG. 2H are briefly given or omitted.

The semiconductor memory device EX3a may include the first channel layer 104, the storage node 134, the second channel layer 136, the first gate insulating layer 126, the second gate insulating layer 140, the bit line 154, the ground electrode 156, and the word line 148-1.

In addition, the semiconductor memory device EX3a may include the work function adjustment layer 158 on one side of the word line 148-1. The word line 148-1 may be configured as a main metal layer. The work function adjustment layer 158 may be formed as a metal layer. The work function adjustment layer 158 may include doped polysilicon, lanthanum oxide, titanium nitride, etc.

Accordingly, the semiconductor device EX3a may easily control a voltage applied to the first channel layer 104 by using the word line 148-1 and the work function adjustment layer 158.

The semiconductor memory device EX3b may include the first channel layer 104, the storage node 134, the second channel layer 136, the first gate insulating layer 126, the second gate insulating layer 140, the bit line 154, the ground electrode 156, and the word line 148-2. The word line 148-2 may not overlap the storage node 134 in the vertical direction (the Z direction). Accordingly, the semiconductor device EX3a may easily adjust the voltage applied to the first channel layer 104 using the word line 148-2.

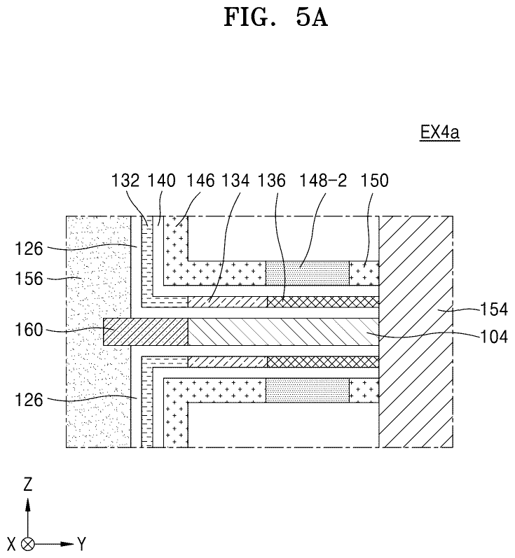

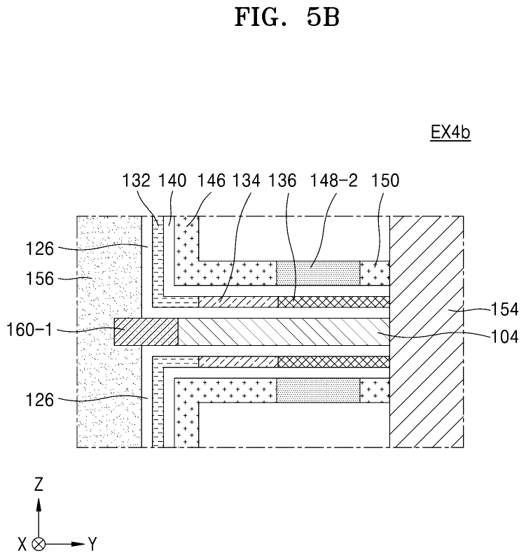

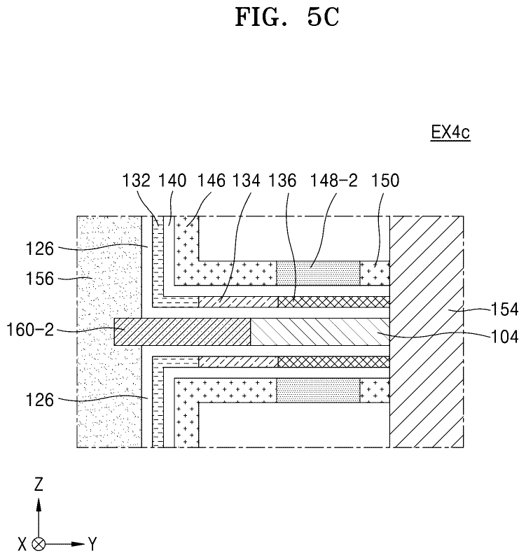

FIGS. 5A to 5C are cross-sectional views illustrating semiconductor memory devices EX4a, EX4b, and EX4c according to implementations.

In detail, the semiconductor memory devices EX4a, EX4b, and EX4c of FIGS. 5A, 5B, and 5C may be the same as the semiconductor memory devices EX1 and EX3b of FIGS. 2H and 4B, except that the semiconductor memory devices EX4a, EX4b, and EX4c further include ground-side channel doping regions 160, 160-1, and 160-2, respectively.

In FIGS. 5A, 5B, and 5C, like reference numerals as those in FIGS. 2H and 4B represent like members. In FIGS. 5A, 5B, and 5C, the same descriptions as those given above with reference to FIGS. 2H and 4B are briefly given or omitted.

The semiconductor memory devices EX4a, EX4b, and EX4c may each include the first channel layer 104, the storage node 134, the second channel layer 136, the first gate insulating layer 126, the second gate insulating layer 140, the bit line 154, the ground electrode 156, and the word line 148-2.

In addition, the semiconductor memory devices EX4a, EX4b, and EX4c may further include the ground-side channel doping regions 160, 160-1, and 160-1 on one side of the first channel layer 104, respectively. The ground-side channel doping regions 160, 160-1, and 160-1 may correspond to the depth of an impurity region doped in the first channel layer 104 in the direction of the ground electrode 156. The ground-side channel doping regions 160, 160-1, and 160-1 may be source and drain regions in contact with the ground electrode 156.

The ground-side channel doping region 160 of the semiconductor memory device EX4a may be aligned with one end of the storage node 134 in the vertical direction (the Z direction). The ground-side channel doping region 160-1 of the semiconductor memory device EX4b may not overlap the storage node 134 in the vertical direction (the Z direction).

The ground-side channel doping region 160-2 of the semiconductor memory device EX4c may overlap the storage node 134 in the vertical direction (the Z direction). In this manner, the semiconductor memory devices EX4a, EX4b, and EX4c may have various configurations of ground-side channel doping regions 160, 160-1, and 160-2.

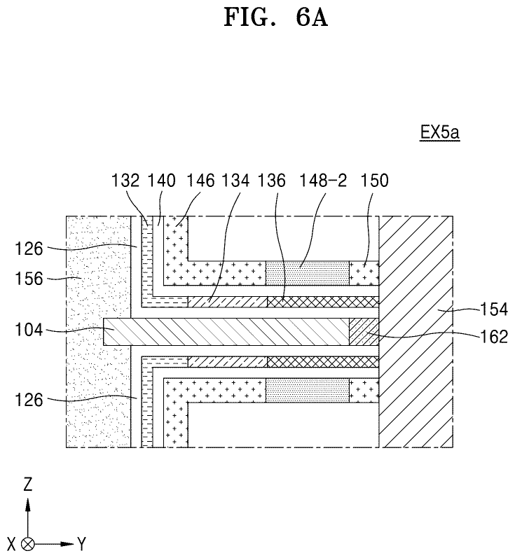

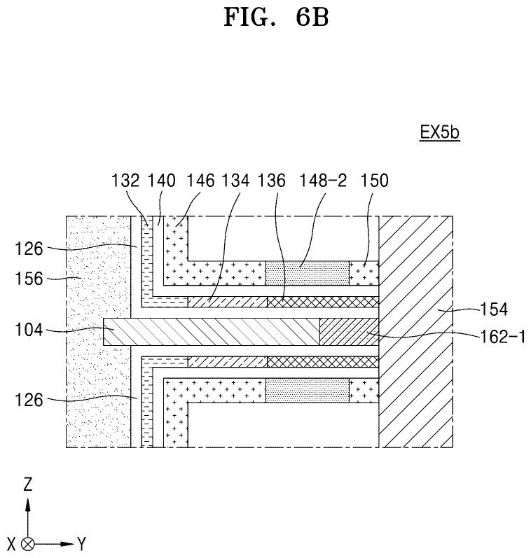

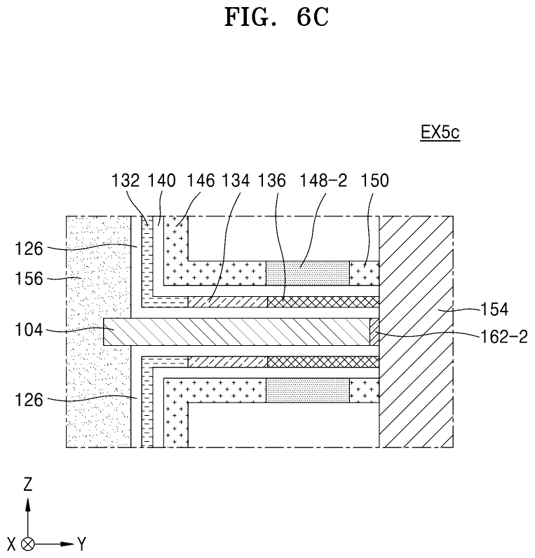

FIGS. 6A, 6B, and 6C are cross-sectional views illustrating semiconductor memory devices EX5a, EX5b, and EX5c according to implementations.

In detail, the semiconductor memory devices EX5a, EX5b, and EX5c of FIGS. 6A, 6B, and 6C may be the same as the semiconductor memory devices EX1 and EX3b of FIGS. 2H and 4B, except that the semiconductor memory devices EX5a, EX5b, and EX5c further include bit line-side channel doping regions 162, 162-1, and 162-2.

In FIGS. 6A, 6B, and 6C, like reference numerals as those in FIGS. 2H and 4B represent like members. In FIGS. 6A, 6B, and 6C, the same descriptions as those given above with reference to FIGS. 2H and 4B are briefly given or omitted.

The semiconductor memory devices EX5a, EX5b, and EX5c may include the first channel layer 104, the storage node 134, the second channel layer 136, the first gate insulating layer 126, the second gate insulating layer 140, the bit line 154, the ground electrode 156, and the word line 148-2.

In addition, the semiconductor memory devices EX5a, EX5b, and EX5c may further include the bit line-side channel doping regions 162, 162-1, and 162-2 on one side of the first channel layer 104, respectively. The bit line-side channel doping regions 162, 162-1, and 162-2 may correspond to the depth of the impurity region doped in the first channel layer 104 in the direction of the bit line 154. The bit line-side channel doping regions 162, 162-1, and 162-2 may be source and drain regions contacting the bit line 154.

The bit line-side channel doping region 162 of the semiconductor memory device EX5a may be aligned with one end of the word line 148-2 in the vertical direction (the Z direction). The bit line-side channel doping region 162-1 of the semiconductor memory device EX5b may overlap the word line 148 in the vertical direction (the Z direction).

The bit line-side channel doping region 162-2 of the semiconductor memory device EX5c may not overlap the word line 148-2 in the vertical direction (the Z direction). In this manner, the semiconductor memory devices EX5a, EX5b, and EX5c may have various configurations of bit line-side channel doping regions 162, 162-1, and 162-2.

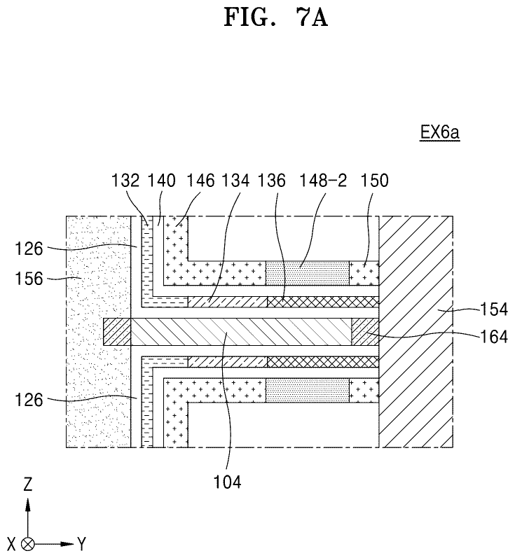

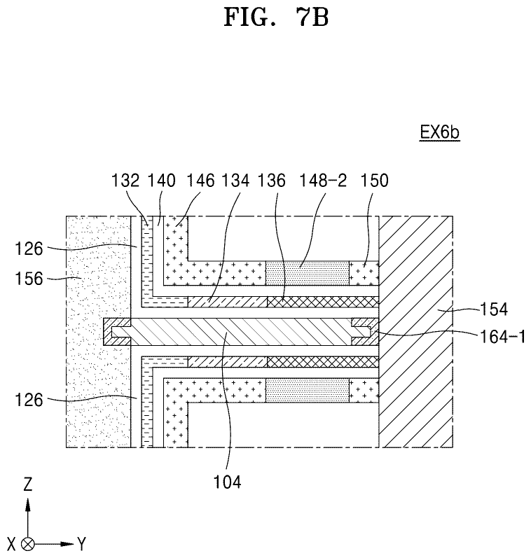

FIGS. 7A and 7B are cross-sectional views illustrating semiconductor memory devices EX6a and EX6b according to implementations.

In detail, the semiconductor memory devices EX6a and EX6b of FIGS. 7A and 7B may be the same as the semiconductor memory devices EX1 and EX3b of FIGS. 2H and 4B, except that the semiconductor memory devices EX6a and EX6b further include silicide layers 164 and 164-1, respectively.

In FIGS. 7A and 7B, reference numerals identical to or similar to those in FIGS. 2H and 4B represent identical or similar members. In FIGS. 7A and 7B, the same contents as in FIGS. 2H and 4B are briefly described or omitted.

The semiconductor memory devices EX6a and EX6b may include the first channel layer 104, the storage node 134, the second channel layer 136, the first gate insulating layer 126, the second gate insulating layer 140, the bit line 154, the ground electrode 156, and the word line 148-2.

In addition, the semiconductor memory devices EX6a and EX6b may further include the silicide layers 164 and 164-1 on one side and the other side of the first channel layer 104. The silicide layers 164 and 164-1 may be formed to reduce contact resistance with the bit line 154 and the ground electrode 156.

The silicide layer 164 of the semiconductor memory device EX6a may be formed on both one side and the other side of the first channel layer 104 in contact with the bit line 154 and the ground electrode 156.

In some implementations, the silicide layer 164 of the semiconductor memory device EX6a may be formed on the first channel layer 104 so as to be in contact with only one of the bit line 154 and the ground electrode 156. The silicide layer 164 may be formed in a square shape on one side and the other side of the first channel layer 104.

The silicide layer 164-1 of the semiconductor memory device EX6b may be formed on both one side and the other side of the first channel layer 104 so as to be in contact with the bit line 154 and the ground electrode 156.

In some implementations, the silicide layer 164-1 of the semiconductor memory device EX6b may be formed on the first channel layer 104 so as to contact only one of the bit line 154 and the ground electrode 156. The silicide layer 164-1 may be formed in a C shape on one side and the other side of the first channel layer 104. In this manner, the semiconductor memory devices EX6a and EX6b may have various configurations of silicide layers 164 and 164-1.

Hereinafter, a method of manufacturing the semiconductor memory device EX1 of FIGS. 2A, 2B, 2C, 2D, 2E, 2F, 2G, and 2H is described.

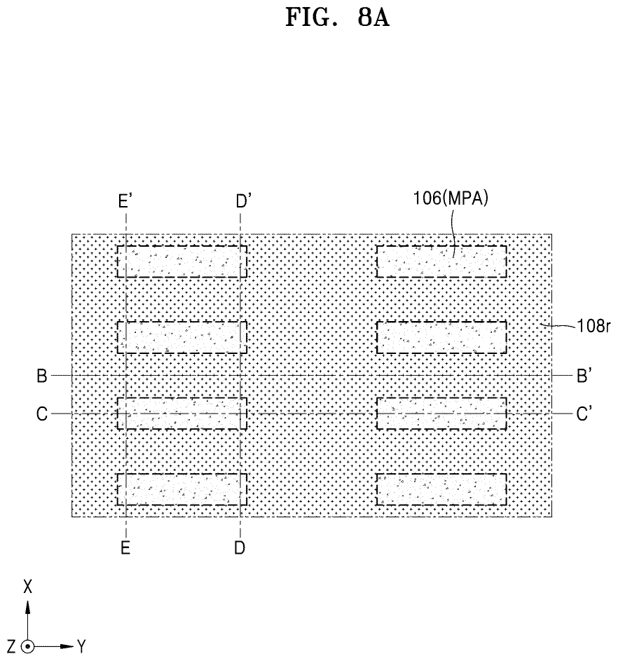

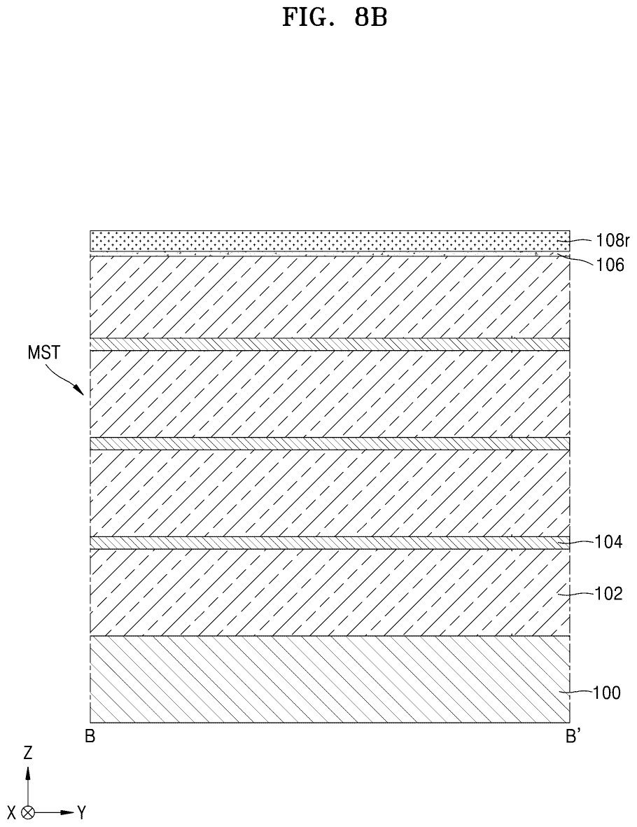

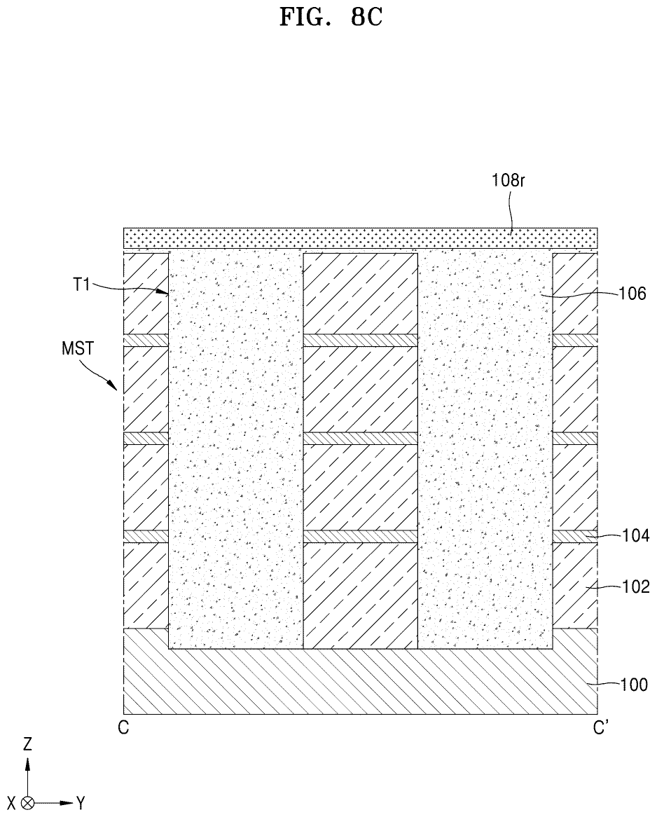

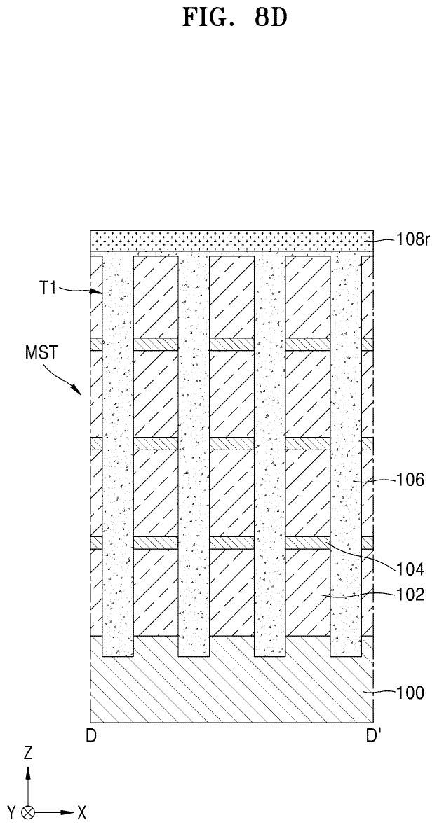

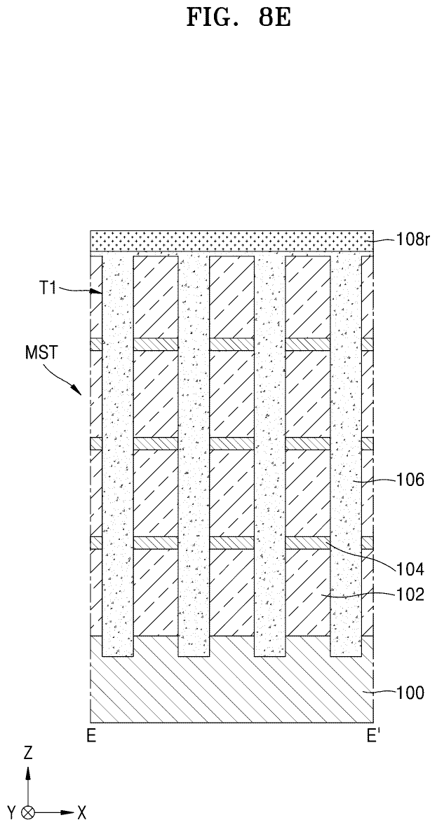

FIGS. 8A, 8B, 8C, 8D, 8E, 9A, 9B, 9C, 9D, 9E, 10A, 10B, 10C, 10D, 10E, 11A, 11B, 11C, 11D, 11E, 12A, 12B, 12C, 12D, 12E, 13A, 13B, 13C, 13D, 13E, 14A, 14B, 14C, 14D, 14E, 15A, 15B, 15C, 15D, 15E, 16A, 16B, 16C, 16D, 16E, 16F, 17A, 17B, 17C, 17D, 17E, 17F, 18A, 18B, 18C, 18D, 18E, 18F, 19A, 19B, 19C, 19D, 19E, and 19F are diagrams illustrating a method of manufacturing a semiconductor memory device, according to some implementations.

In detail, FIGS. 8A, 8B, 8C, 8D, 8E, 9A, 9B, 9C, 9D, 9E, 10A, 10B, 10C, 10D, 10E, 11A, 11B, 11C, 11D, 11E, 12A, 12B, 12C, 12D, 12E, 13A, 13B, 13C, 13D, 13E, 14A, 14B, 14C, 14D, 14E, 15A, 15B, 15C, 15D, 15E, 16A, 16B, 16C, 16D, 16E, 16F, 17A, 17B, 17C, 17D, 17E, 17F, 18A, 18B, 18C, 18D, 18E, 18F, 19A, 19B, 19C, 19D, 19E, and 19F are diagrams illustrating a method of manufacturing the semiconductor memory device EX1 of FIGS. 2A, 2B, 2C, 2D, 2E, 2F, and 2G. In FIGS. 8A, 8B, 8C, 8D, 8E, 9A, 9B, 9C, 9D, 9E, 10A, 10B, 10C, 10D, 10E, 11A, 11B, 11C, 11D, 11E, 12A, 12B, 12C, 12D, 12E, 13A, 13B, 13C, 13D, 13E, 14A, 14B, 14C, 14D, 14E, 15A, 15B, 15C, 15D, 15E, 16A, 16B, 16C, 16D, 16E, 16F, 17A, 17B, 17C, 17D, 17E, 17F, 18A, 18B, 18C, 18D, 18E, 18F, 19A, 19B, 19C, 19D, 19E, and 19F, the same descriptions as those given above with reference to FIGS. 2A, 2B, 2C, 2D, 2E, 2F, and 2G are briefly given or omitted.

FIGS. 8A, 8B, 8C, 8D, 8E, 9A, 9B, 9C, 9D, 9E, 10A, 10B, 10C, 10D, 10E, 11A, 11B, 11C, 11D, 11E, 12A, 12B, 12C, 12D, 12E, 13A, 13B, 13C, 13D, 13E, 14A, 14B, 14C, 14D, 14E, 15A, 15B, 15C, 15D, 15E, 16A, 16B, 16C, 16D, 16E, 16F, 17A, 17B, 17C, 17D, 17E, 17F, 18A, 18B, 18C, 18D, 18E, 18F, 19A, 19B, 19C, 19D, 19E, and 19F are layout diagrams of intermediate operations in the manufacturing process of a semiconductor memory device. FIGS. 8B, 9B, 10B, 11B, 12B, 13B, 14B, 15B, 16B, 17B, 18B and 19B are cross-sectional views taken along line B-B′ of FIGS. 8A, 9A, 10A, 11A, 12A, 13A, 14A, 15A, 16A, 17A, 18A, and 19A, respectively. FIGS. 8C, 9C, 10C, 11C, 12C, 13C, 14C, 15C, 16C, 17C, 18C, and 19C are cross-sectional views taken along line C-C′ of FIGS. 8A, 9A, 10A, 11A, 12A, 13A, 14A, 15A, 16A, 17A, 18A, and 19A, respectively.

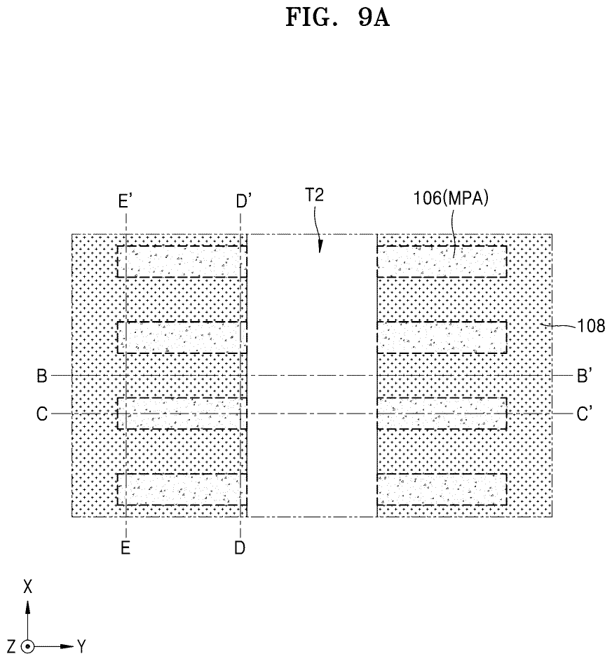

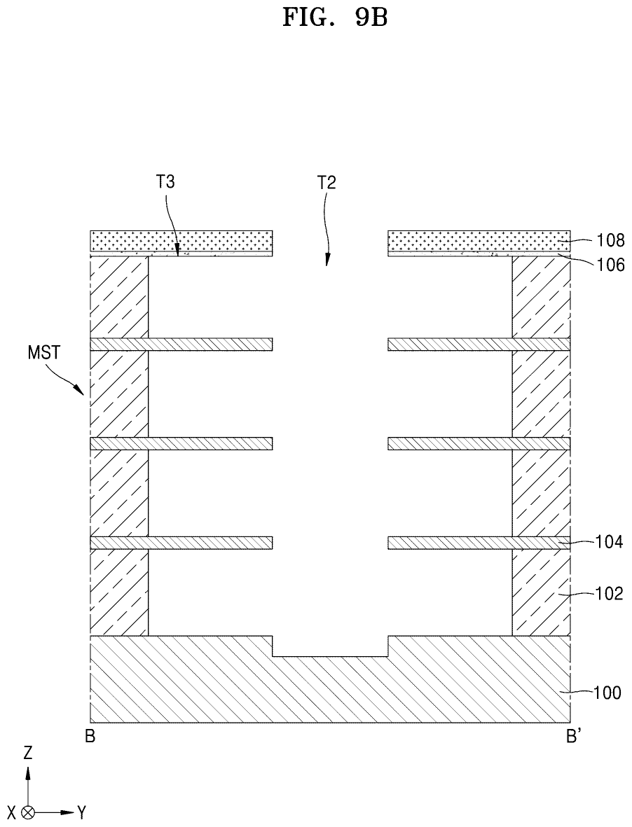

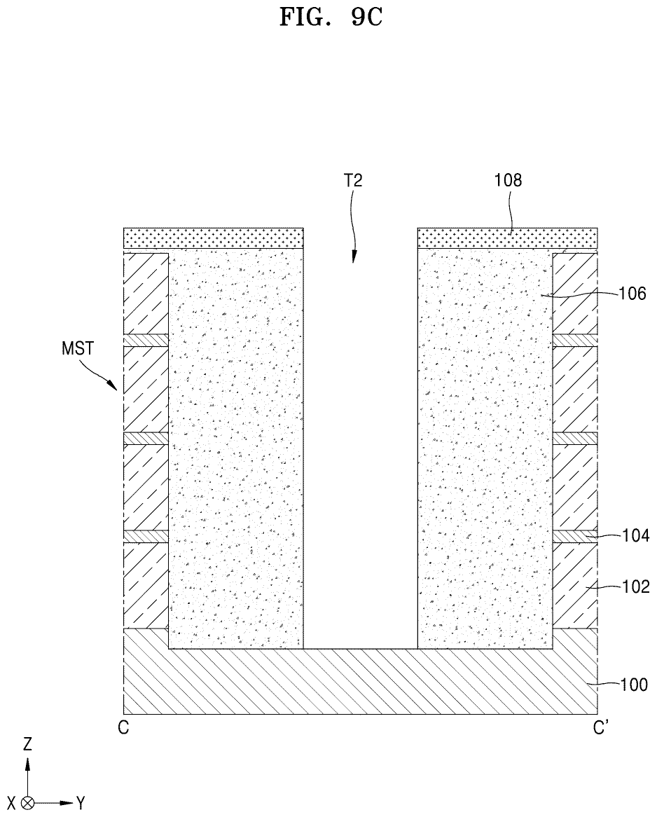

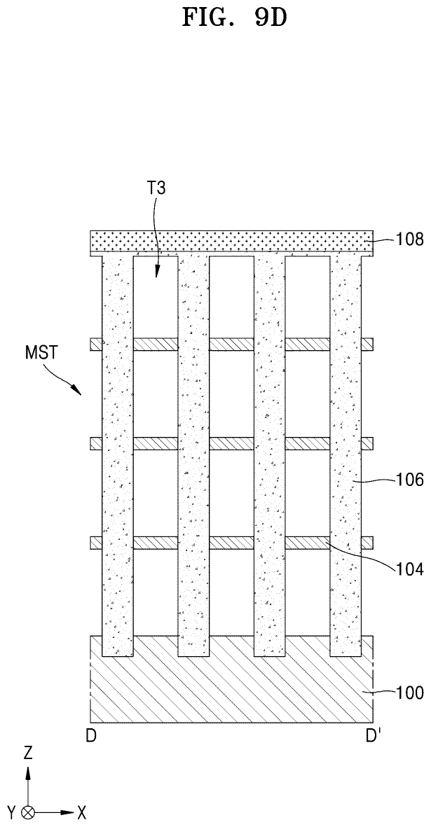

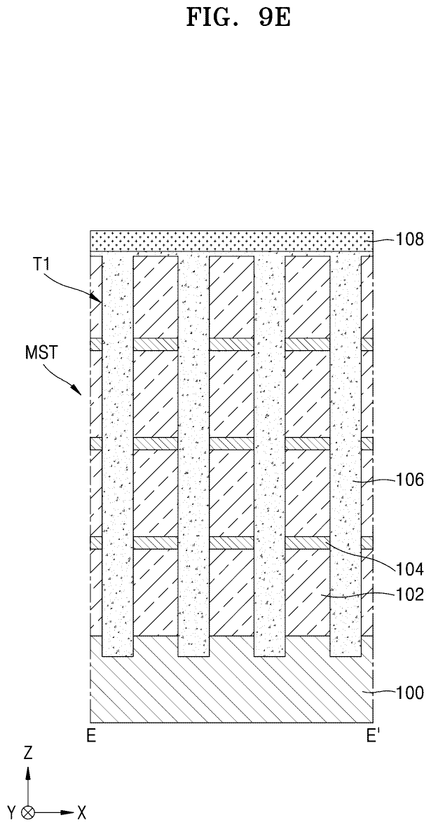

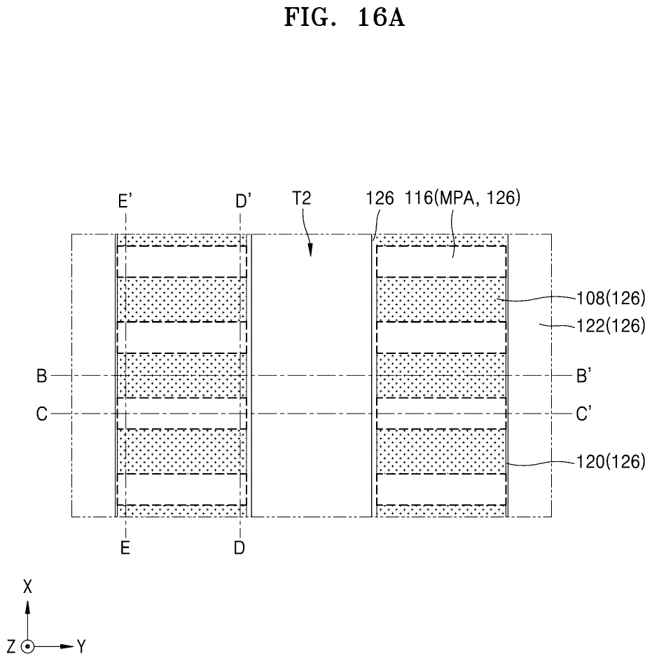

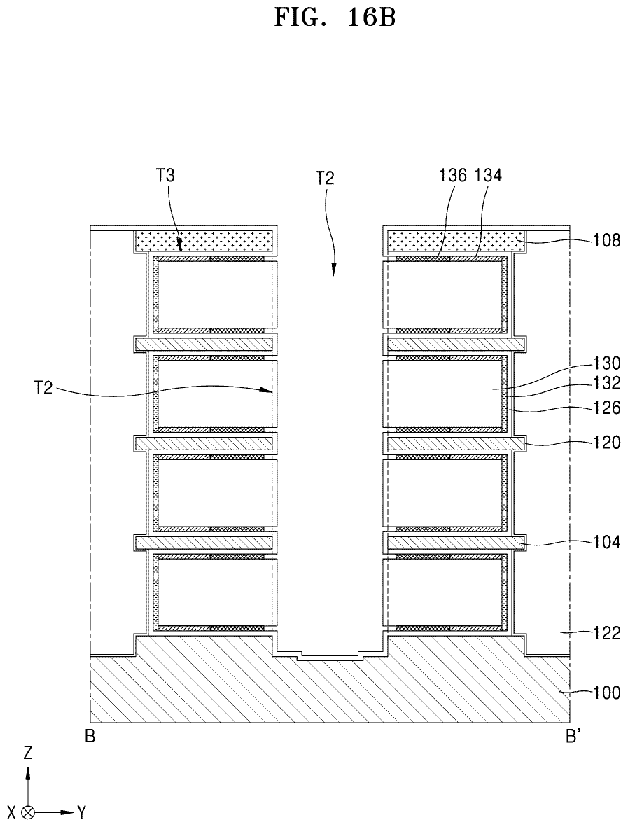

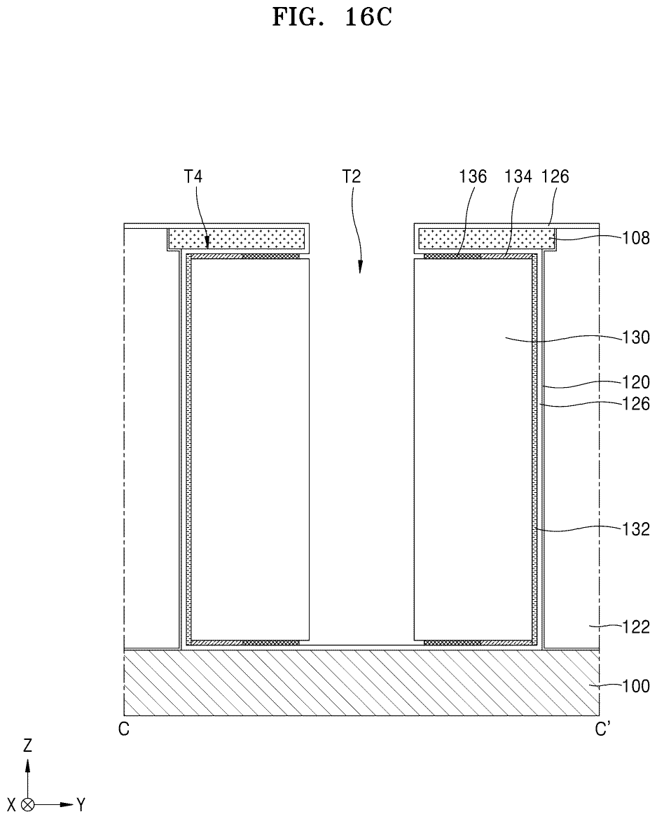

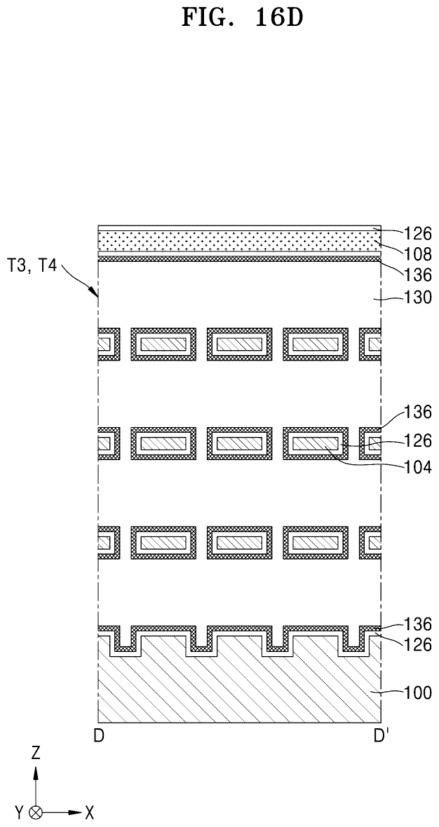

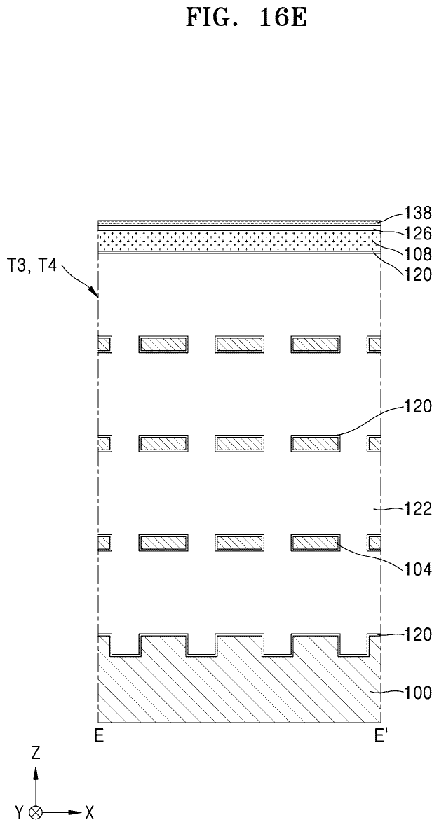

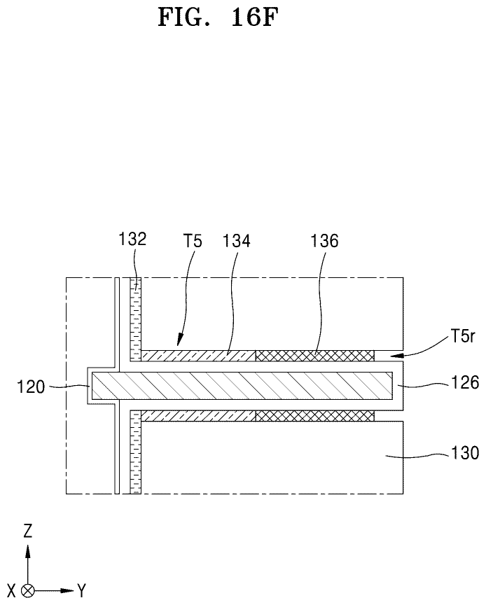

FIGS. 9D, 10D, 11D, 12D, 13D, 14D, 15D, 16D, 17D, 18D, and 19D are cross-sectional views taken along lines D-D′ of FIGS. 8A, 9A, 10A, 11A, 12A, 13A, 14A, 15A, 16A, 17A, 18A, and 19A, respectively. FIGS. 9E, 10E, 11E, 12E, 13E, 14E, 15E, 16E, 17E, 18E, and 19E are cross-sectional views taken along lines E-E′ of FIGS. 8A, 9A, 10A, 11A, 12A, 13A, 14A, 15A, 16A, 17A, 18A, and 19A, respectively. FIGS. 16F, 17F, 18F, and 19F are enlarged cross-sectional views of portions of FIGS. 16B, 17B, 18B, and 19B, respectively.

FIGS. 8A, 8B, 8C, 8D, and 8E include forming a memory stack layer MST including the first channel layer 104, the mold pattern MPA, and a mold cover material layer 108r on the substrate 100.

In detail, the memory stack layer MST including a sacrificial semiconductor layer 102 and the first channel layer 104 is formed on the substrate 100. In some implementations, the first channel layer 104 may include crystalline silicon. In some implementations, the sacrificial semiconductor layer 102 may include a silicon germanium material.

The first trench T1 is formed within the memory stack layer MST, and a first mold layer 106 forming the mold pattern MPA is formed within the first trench T1. The mold cover material layer 108r is formed on the first mold layer 106 and the memory stack layer MST. In some implementations, the first mold layer 106 may include silicon oxide. In some implementations, the mold cover material layer 108r may include silicon nitride.

Referring to FIG. 8A, the mold pattern MPA is formed inside the mold cover material layer 108r in the layout. The mold patterns MPA are apart in the first horizontal direction (the X direction) and the second horizontal direction (the Y direction).

Referring to FIG. 8B, the memory stack layer MST and the mold cover material layer 108r are formed on the substrate 100. The memory stack layer MST includes the sacrificial semiconductor layer 102 and the first channel layer 104 sequentially formed on the substrate 100. The first mold layer 106 and the mold cover material layer 108r constituting the mold pattern MPA are formed on the uppermost sacrificial semiconductor layer 102 constituting the memory stack layer MST.

Referring to FIG. 8C, the first trench T1 is formed in the memory stack layer MST including the sacrificial semiconductor layer 102 and the first channel layer 104. The first mold layer 106 forming the mold pattern MPA is formed within the first trench T1. The mold cover material layer 108r is formed on the first mold layer 106 and the memory stack layer MST.

Referring to FIGS. 8D and 8E, the first trench T1 is formed in the memory stack layer MST including the sacrificial semiconductor layer 102 and the first channel layer 104 on the substrate 100. A width of the first trench T1 illustrated in FIG. 8D and FIG. 8E is less than that of the first trench T1 illustrated in FIG. 8C. The first mold layer 106 forming the mold pattern MPA is formed within the first trench T1. The mold cover material layer 108r is formed on the first mold layer 106 and the memory stack layer MST.

FIGS. 9A, 9B, 9C, 9D, and 9E illustrate forming the second trench T2, the third trench T3, and the mold cover layer 108.

In detail, the mold cover layer 108 is formed by patterning the mold cover material layer (108r in FIG. 8B). The memory stack layer MST including the sacrificial semiconductor layer 102 and the first channel layer 104 is patterned to form the second trench T2. The sacrificial semiconductor layer 102 is etched in the second horizontal direction (the Y direction) to form the third trench T3.

Referring to FIG. 9A, the mold cover material layer (108r of FIG. 8A) in the layout is patterned to form the second trench T2. The second trench T2 extends in the first horizontal direction (the X direction). The second trench T2 may be formed between the mold patterns MPA in the first horizontal direction (the X direction) and the second horizontal direction (the Y direction).

Referring to FIG. 9B, the mold cover material layer (108r of FIG. 8B) is patterned on the memory stack layer MST to form the mold cover layer 108. The first mold layer 106 may be formed below the mold cover layer 108. The memory stack layer MST including the sacrificial semiconductor layer 102 and the first channel layer 104 is patterned to form the second trench T2.

Subsequently, the sacrificial semiconductor layer 102 is etched in the second horizontal direction (the Y direction) to form the third trench T3. The third trench T3 may be formed between a lower portion of the mold cover layer 108 and the first channel layer 104 constituting the memory stack layer MST.

The third trench T3 may communicate with the second trench T2. The third trench T3 may be a recessed trench recessed in the second horizontal direction (Y direction or −Y direction) from one sidewall of the mold cover layer 108. A portion of the first channel layer 104 may be exposed as the second trench T2 and the third trench T3 are formed. In some implementations, the thickness of the first channel layer 104 exposed to the second trench T2 and the third trench T3 may be further etched to be reduced.

Referring to FIG. 9C, the mold cover material layer (108r of FIG. 8B) is patterned on the memory stack layer MST to form the mold cover layer 108. The memory stack layer MST including the sacrificial semiconductor layer 102 and the first channel layer 104 is patterned to form the second trench T2. The second trench T2 may be in contact with the first mold layer 106 forming the mold pattern MPA.

Referring to FIG. 9D, the sacrificial semiconductor layer (102 of FIG. 8D) forming the memory stack layer MST on the substrate 100 is etched to form the third trench T3. The third trench T3 may be formed below the mold cover layer 108. The third trench T3 may be formed between the first mold layers 106 constituting the mold pattern MPA and the first channel layers 104 constituting the memory stack layer MST.

Referring to FIG. 9E, the mold cover material layer (108r of FIG. 8E) is patterned on the memory stack layer MST to form the mold cover layer 108. The mold cover layer 108 is formed on the first mold layer 106 and the memory stack layer MST. The first mold layer 106 may be formed within the first trench T1 in the memory stack layer MST below the mold cover layer 108.

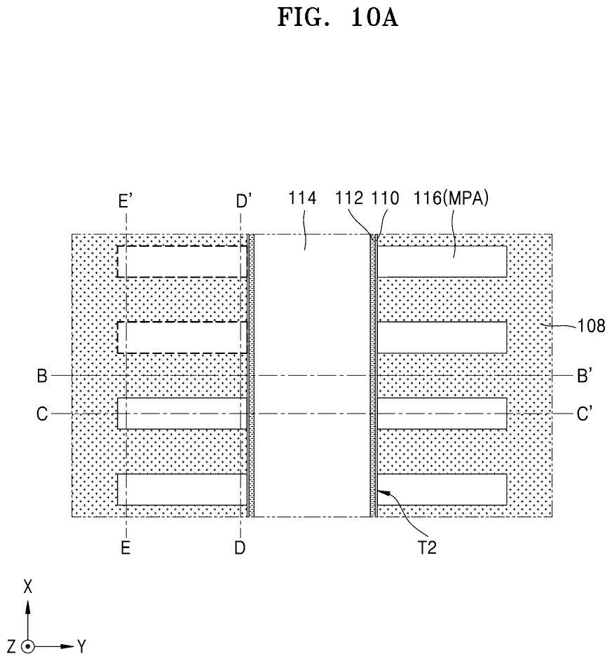

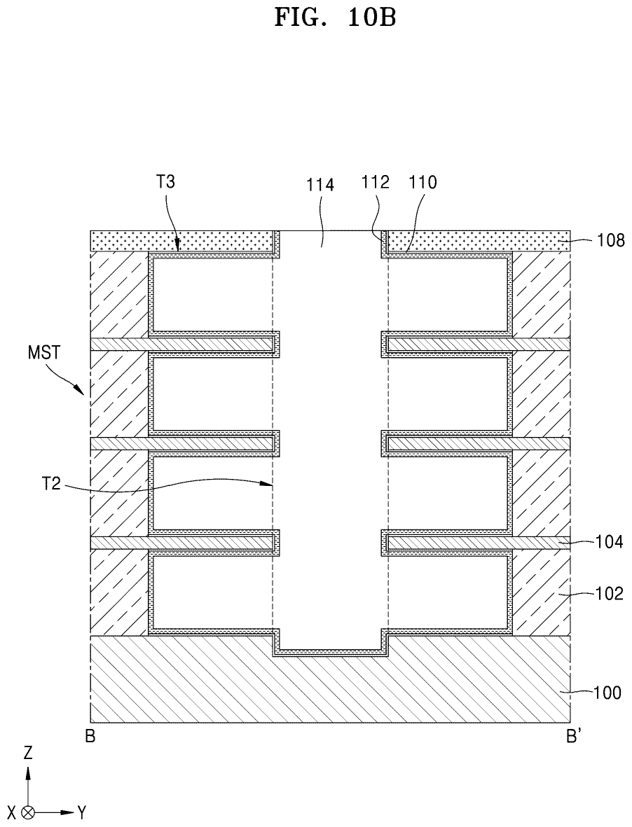

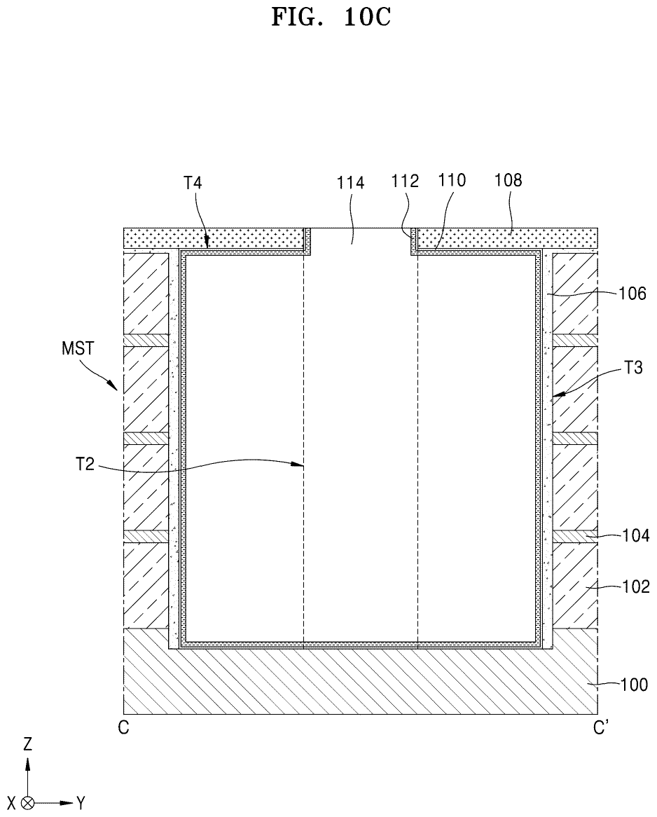

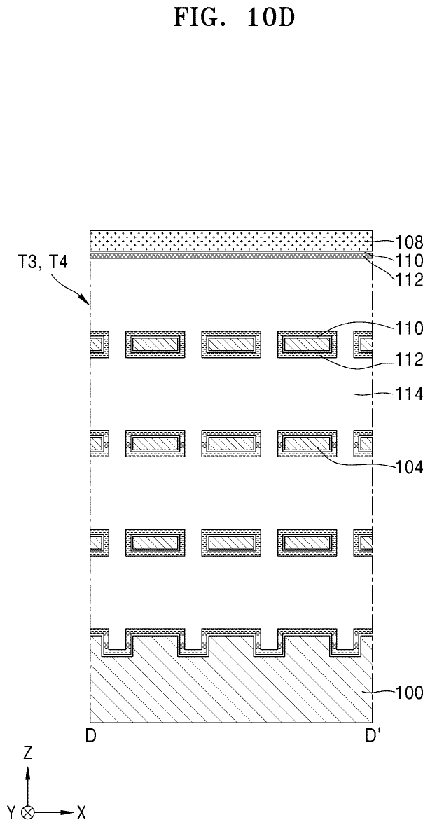

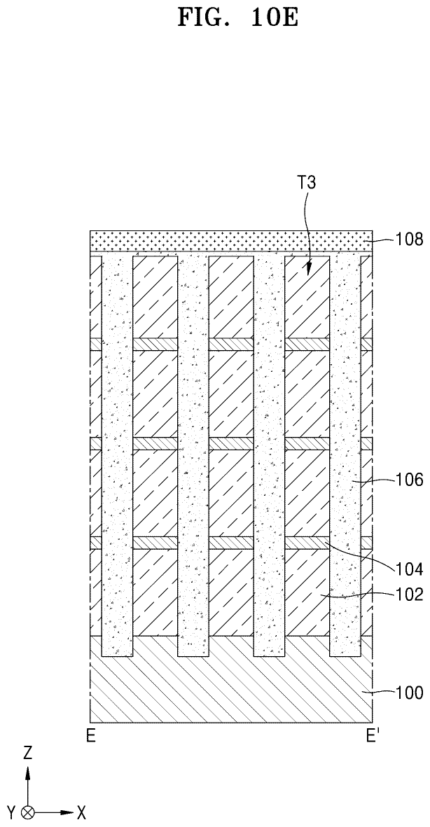

FIGS. 10A, 10B, 10C, 10D, and 10E illustrate forming a first liner layer 110, a second liner layer 112, and a first buried insulating layer 114.

In detail, the first mold layer (106 in FIGS. 9C and 9D) is etched to form the fourth trench T4 and a second mold layer 116. The first liner layer 110 and the second liner layer 112 are sequentially formed on inner walls of the second trench T2, the third trench T3, and the fourth trench T4 and on the surface of the first channel layer 104. In some implementations, the first liner layer 110 and the second liner layer 112 may include silicon nitride and silicon oxide, respectively.

The first buried insulating layer 114 is formed to fill the second trench T2, the third trench T3, and the fourth trench T4 on the second liner layer 112. In some implementations, the first buried insulating layer 114 may include silicon oxide.

Referring to FIG. 10A, the first mold layer (106 of FIG. 9A) is etched to form the second mold layer 116. The second mold layer 116 may form the mold pattern MPA. In the layout, the first liner layer 110 and the second liner layer 112 are formed inside the second trench T2.

The first buried insulating layer 114 is formed within the second trench T2. The second mold layer 116 may include the first liner layer 110, the second liner layer 112, and the first buried insulating layer 114. The first liner layer 110, the second liner layer 112, and the first buried insulating layer 114 extend in the first horizontal direction (the X direction).

Referring to FIG. 10B, the first liner layer 110 and the second liner layer 112 are sequentially formed on the inner walls of the second trench T2 and the third trench T3, one sidewall of the sacrificial semiconductor layer 102, the surface of the first channel layer 104 exposed in the second trench T2 and the third trench T3, and one sidewall of the mold cover layer 108.

The first buried insulating layer 114 is formed to fill both the second trench T2 and the third trench T3 on the second liner layer 112. The first buried insulating layer 114 is formed between the first channel layers 104 in the vertical direction (the Z direction).

Referring to FIG. 10C, the first mold layer (106 of FIG. 9C) is further etched to form the fourth trench T4. The fourth trench T4 may be formed below the mold cover layer 180. The first mold layer 106 may remain on one sidewall of the fourth trench T4.

The first liner layer 110 and the second liner layer 112 are sequentially formed on the inner wall of the fourth trench T4, one sidewall of the first mold layer 106, and one sidewall of the mold cover layer 108. The first buried insulating layer 114 is formed to fill both the second trench T2 and the fourth trench T4 on the second liner layer 112.

Referring to FIG. 10D, the first mold layer (106 of FIG. 9D) is etched to form the fourth trench T4. The fourth trench T4 may communicate with the third trench T3. Accordingly, the first channel layers 104 may be formed apart from each other in the first horizontal direction (the X direction) and vertical direction (the Z direction) on the substrate 100 as the third trench T3 and the fourth trench T4 are formed. An uneven structure may be formed on the substrate 100 as the first mold layer (106 in FIG. 9D) is etched.

The first liner layer 110 and the second liner layer 112 are sequentially formed to surround the first channel layer 104 in the third trench T3 and the fourth trench T4. The first buried insulating layer 114 is formed to fill the inside of the third trench T3 and the fourth trench T4. The first buried insulating layer 114 may be formed between the first channel layers 104.

Referring to FIG. 10E, the structure may be the same as that of FIG. 9E. The mold cover layer 108 is formed on the memory stack layer MST. The mold cover layer 108 is formed on the first mold layer 106 and the memory stack layer MST. The first mold layer 106 is formed within the first trench T1 in the memory stack layer MST below the mold cover layer 108.

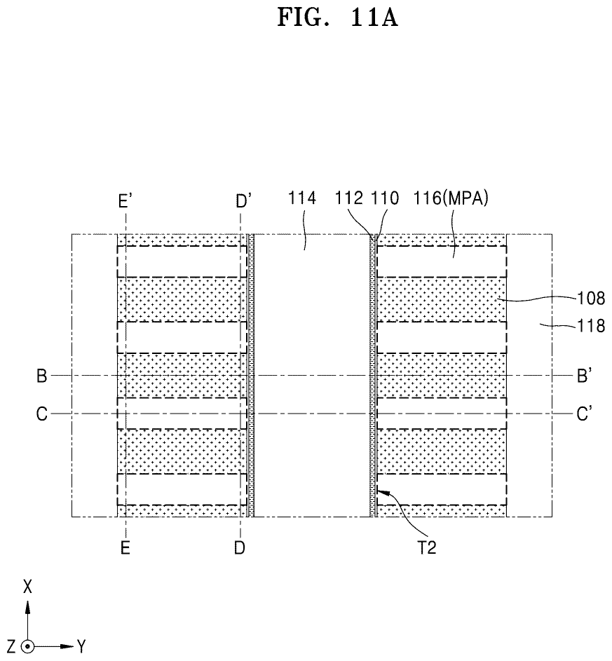

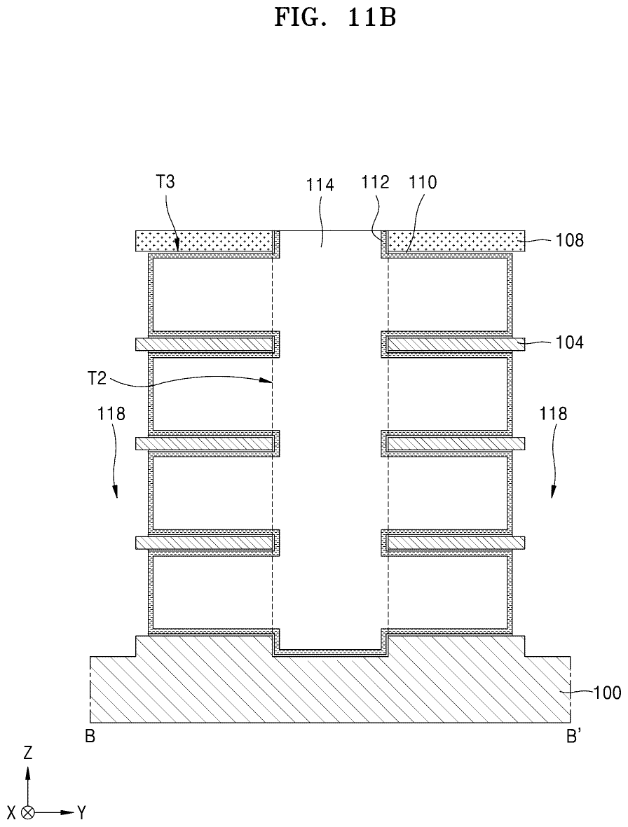

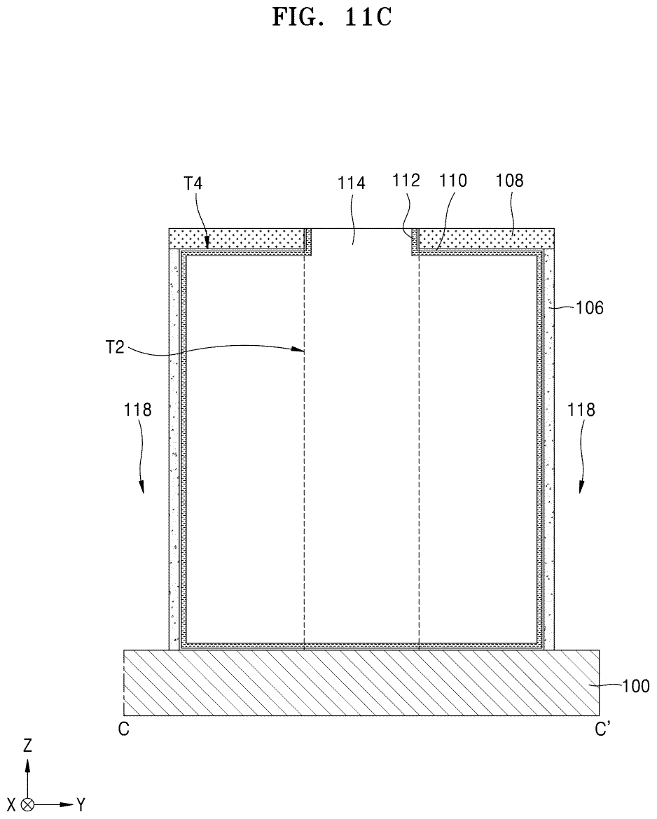

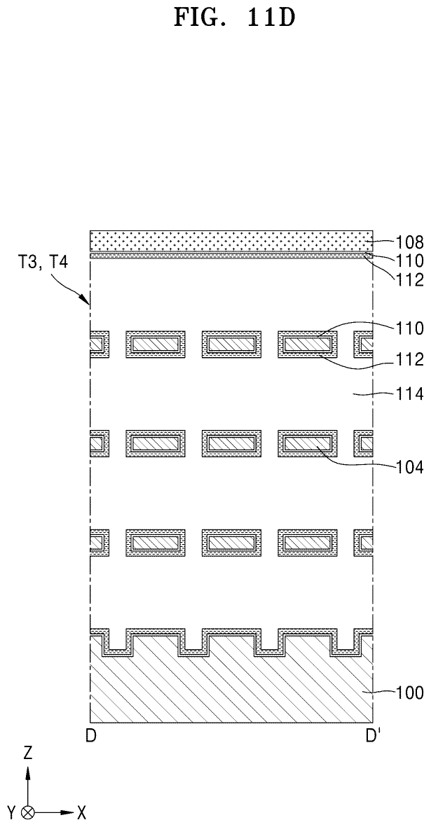

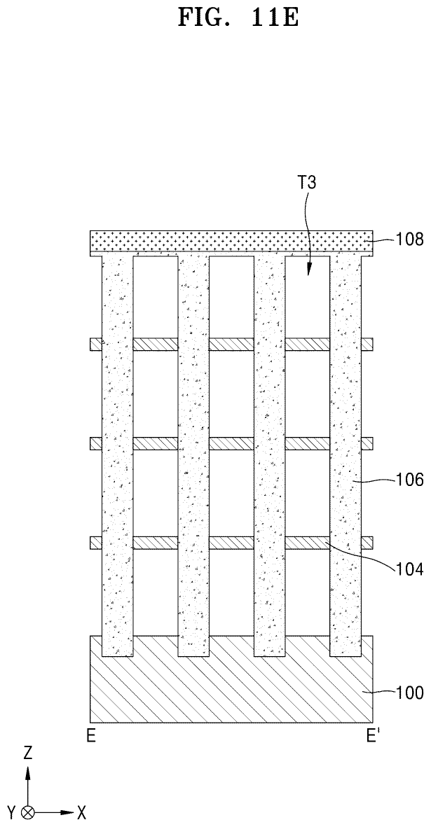

FIGS. 11A, 11B, 11C, 11D, and 11E illustrate forming a ground trench 118 and etching the sacrificial semiconductor layer 102 that constitutes the memory stack layer MST.

In detail, the memory stack layer MST outside the third trench T3 and the fourth trench T4 below the mold cover layer 108 is etched to form the ground trench 118. Subsequently, the sacrificial semiconductor layer 102 outside the third trench T3 is recess-etched below the mold cover layer 108 to form the first channel layer 104 so as to protrude relative to one sidewall of the third trench T3.

Referring to FIG. 11A, the ground trench 118 is formed outside the mold pattern MPA and the mold cover layer 108 in the layout. The ground trench 118 may be formed by etching the memory stack layer (MST of FIGS. 10B and 10C) below the mold cover layer 108.

Referring to FIG. 11B, the memory stack layer (MST of FIG. 10B) outside the third trench T3 below the mold cover layer 108 is etched to form the ground trench 118. The ground trench 118 may expose the substrate 100.

Subsequently, the sacrificial semiconductor layer 102 outside the third trench T3 below the mold cover layer 108 is recess-etched in the second horizontal direction (the Y direction) to form the first channel layer 104 so as to protrude relative to one sidewall of the third trench T3. In some implementations, an impurity doping region for forming a junction may be further formed in the first channel layer 104 protruding relative to one sidewall of the third trench T3.

Referring to FIG. 11C, the memory stack layer (MST of FIG. 10C) outside the fourth trench T4 below the mold cover layer 108 is etched to form the ground trench 118. The ground trench 118 may expose the substrate 100.

In some implementations, when forming the ground trench 118, one end portion of the mold cover layer 108 may also be etched so that one sidewall of the first mold layer 106 may be flush with one sidewall of the mold cover layer 108 in the vertical direction (the Z direction). In some implementations, the first mold layer 106 below the mold cover layer 108 may be etched during or after the formation of the ground trench 118.

Referring to FIG. 11D, the first liner layer 110 and the second liner layer 112 are formed to surround the first channel layer 104 in the third trench T3 and the fourth trench T4 similarly to FIG. 10D. The first buried insulating layer 114 is formed to fill the inside of the third trench T3 and the fourth trench T4. The first buried insulating layer 114 may be formed between the first channel layers 104.

Referring to FIG. 11E, the sacrificial semiconductor layer 102 below the mold cover layer 108 is etched to form the third trench T3. The third trench T3 of FIG. 11E may be a trench communicating with the third trench T3 illustrated in FIGS. 9B and 10B. The mold cover layer 108 is formed on the first mold layer 106. The first channel layers 104 are apart from each other in the first horizontal direction (the X direction) and vertical direction (the Z direction) by the first mold layer 106.

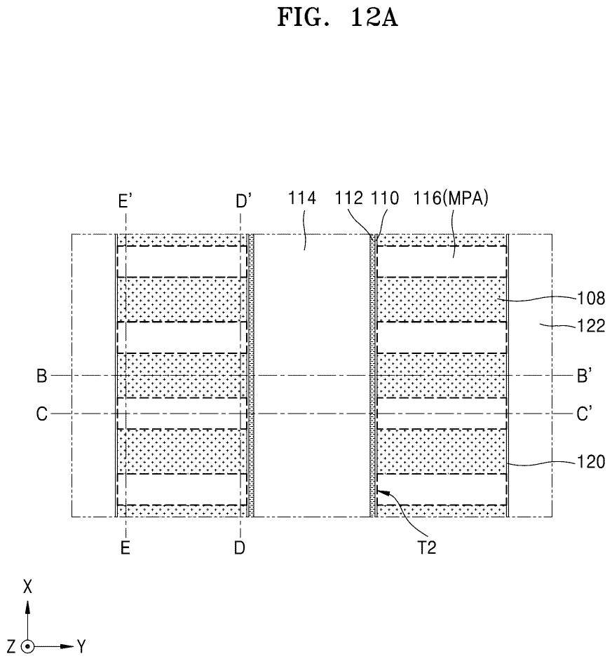

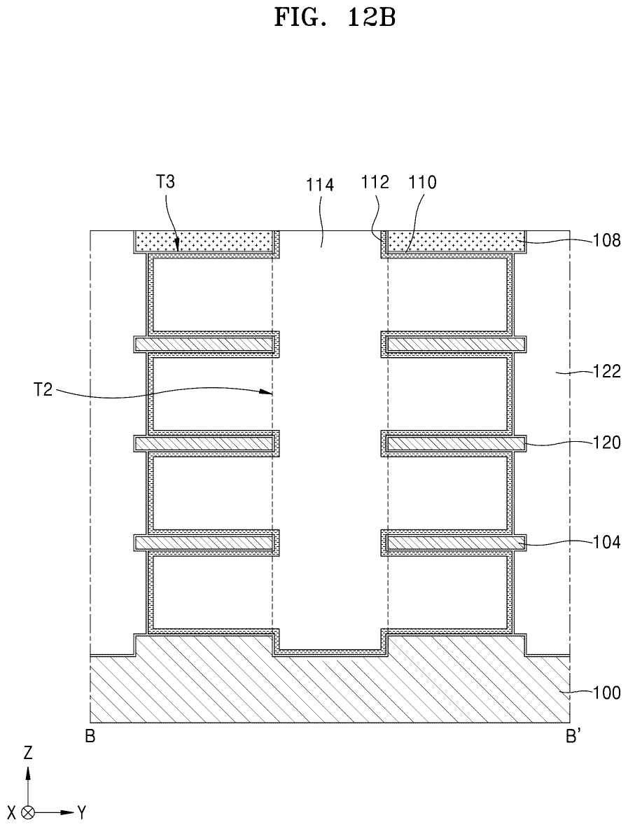

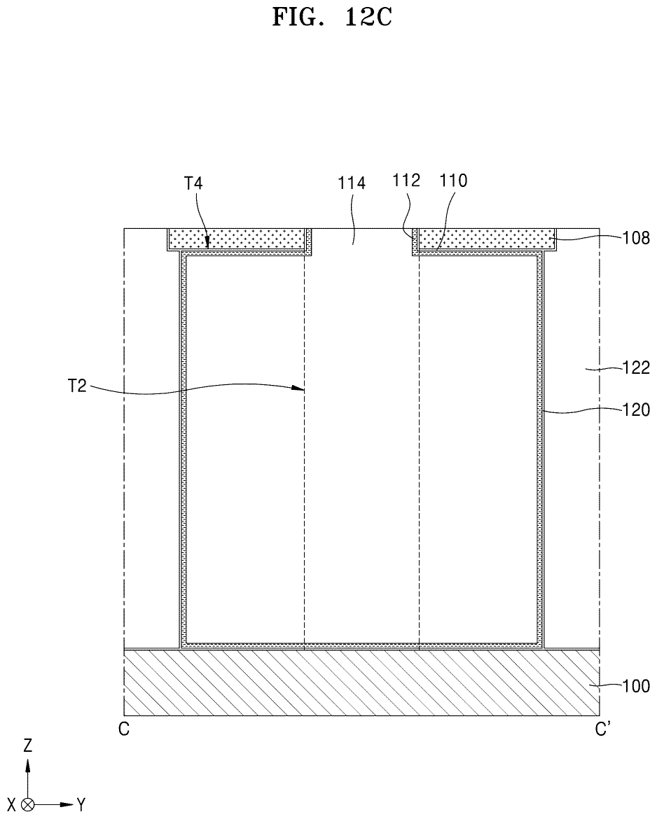

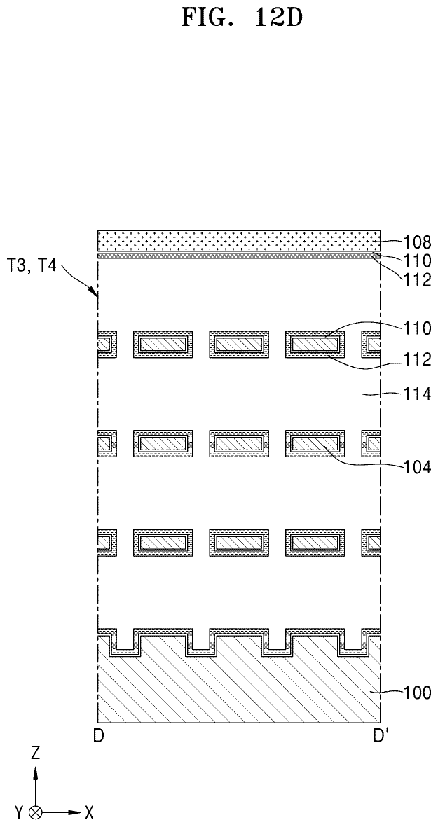

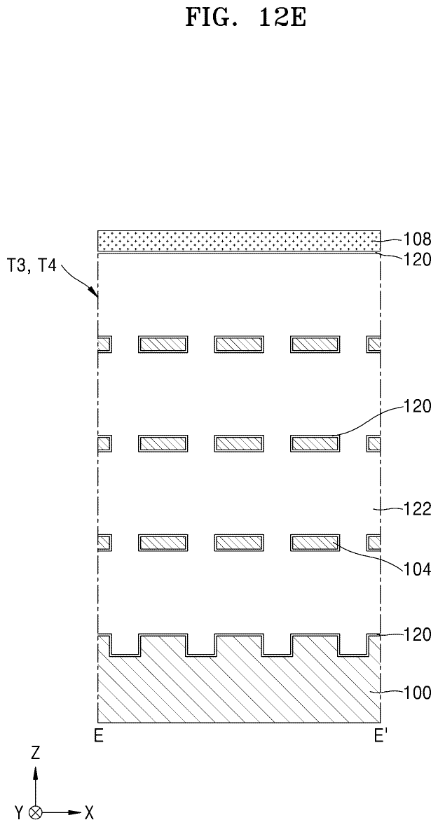

FIGS. 12A, 12B, 12C, 12D, and 12E illustrate forming the third liner layer 120 and the second buried insulating layer 122 within the ground trench 118.

In detail, the third liner layer 120 is formed on one sidewall of the ground trench (118 of FIGS. 11A, 11B, and 11C) formed in the substrate 100, and the second buried insulating layer 122 is formed on one side of the third liner layer 120 to fill the ground trench (118 of FIGS. 11A, 11B, and 11C). In some implementations, the third liner layer 120 may include silicon oxide. In some implementations, the second buried insulating layer 122 may include silicon oxide.

Referring to FIG. 12A, the third liner layer 120 and the second buried insulating layer 122 are formed in the ground trench (118 of FIG. 11A) outside the mold pattern MPA and the mold cover layer 108 in the layout. The third liner layer 120 and the second buried insulating layer 122 may extend in the first horizontal direction (the X direction).

Referring to FIG. 12B, the third liner layer 120 and the second buried insulating layer 122 are formed in the ground trench (118 of FIG. 11B) outside the mold cover layer 108 and outside the third trench T3. The second buried insulating layer 122 may be formed to cover the first channel layer 104 and the third liner layer 120 protruding outward from the second trench T2 and the third trench T3 on the substrate 100.

Referring to FIG. 12C, the third liner layer 120 and the second buried insulating layer 122 are formed in the ground trench (118 of FIG. 11C) outside the fourth trench T4 below the mold cover layer 108. The second buried insulating layer 122 may be formed to cover the third liner layer 120 outside the second trench T2 and the fourth trench T4 on the substrate 100.

Referring to FIG. 12D, the first liner layer 110 and the second liner layer 112 are formed to surround the first channel layer 104 in the third trench T3 and the fourth trench T4, similarly to FIG. 11D. The first buried insulating layer 114 is formed to fill the inside of the third trench T3 and the fourth trench T4. The first buried insulating layer 114 may be formed between the first channel layers 104.

Referring to FIG. 12E, the first mold layer (106 of FIG. 11E) below the mold cover layer 108 is etched to form the fourth trench T4. The fourth trench T4 of FIG. 12E may be a trench communicating with the third trench T3 illustrated in FIGS. 9E and 10E. The first channel layers 104 are apart from each other in the first horizontal direction (the X direction) and the vertical direction (the Z direction) according to the third trench T3 and the fourth trench T4. An uneven structure may be formed on the substrate 100 as the first mold layer (106 in FIG. 11E) is etched.

Subsequently, the third liner layer 120 is formed to surround the first channel layer 104. The second buried insulating layer 122 is formed to fill the inside of the third trench T3 and the fourth trench T4 on the third liner layer 120. The second buried insulating layer 122 may be formed between the first channel layers 104 in the first horizontal direction (the X direction) and vertical direction (the Z direction).

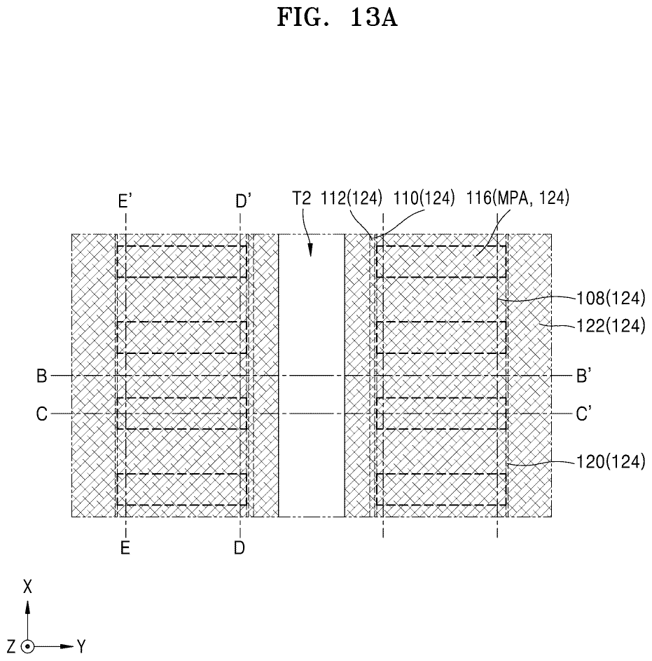

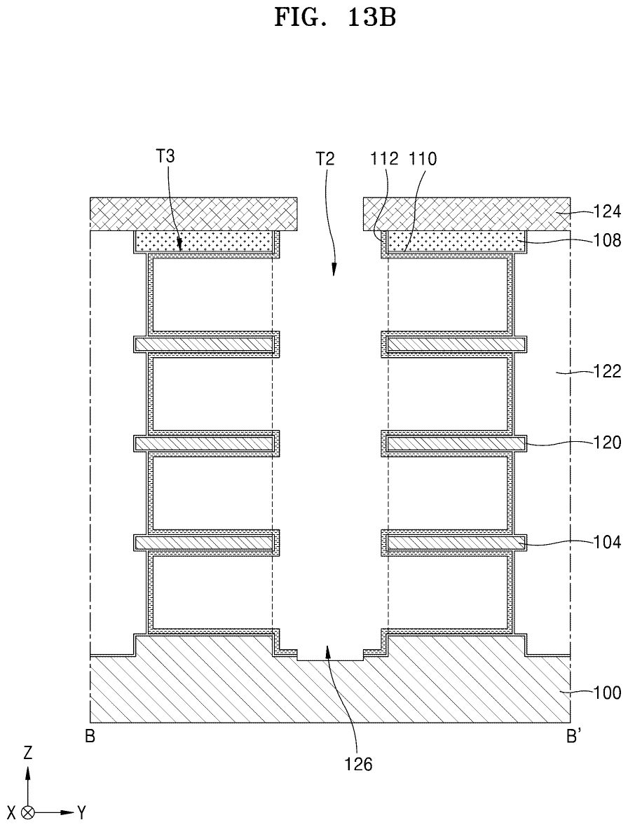

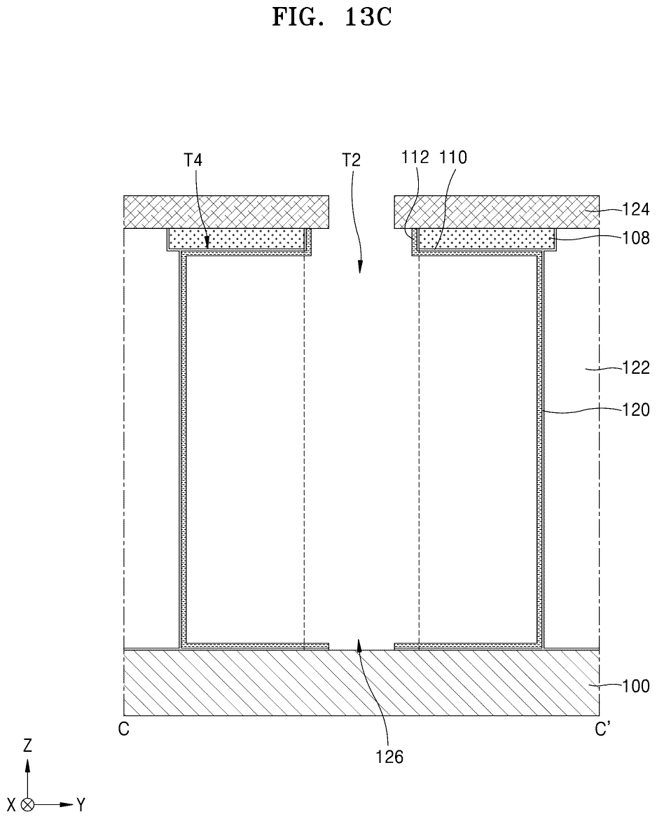

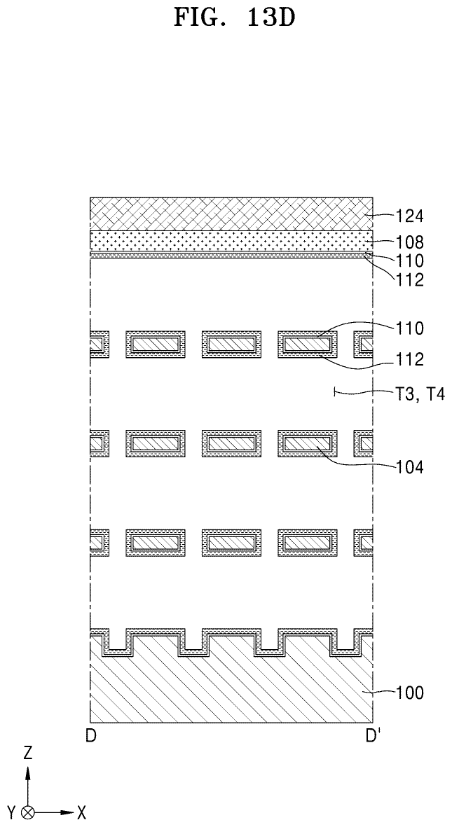

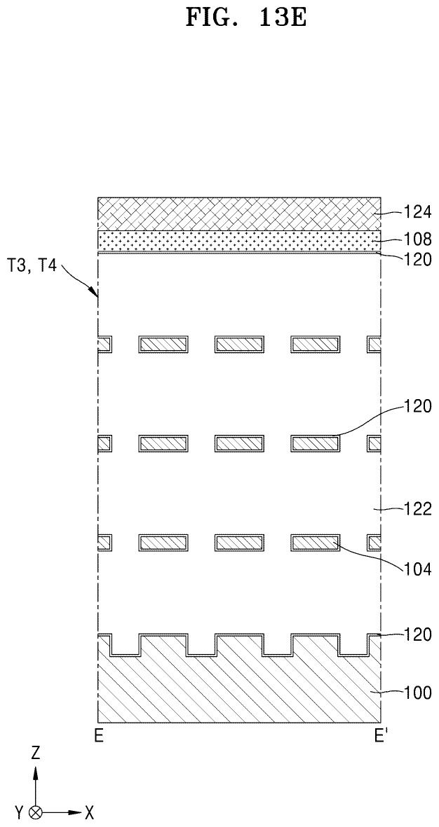

FIGS. 13A, 13B, 13C, 13D, and 13E illustrate forming an etch stop pattern 124 and etching the first buried insulating layer 114. In detail, the etch stop pattern 124 is formed on the mold cover layer 108, the first liner layer 110, the second liner layer 112, the third liner layer 120, and the second buried insulating layer 122. In some implementations, the etch stop pattern 124 may include silicon nitride. Subsequently, the first buried insulating layer 114 in the second trench T2, the third trench T3, and the fourth trench T4 is etched.

Referring to FIG. 13A, the etch stop pattern 124 is formed on the mold pattern MPA, the mold cover layer 108, the first liner layer 110, the second liner layer 112, the third liner layer 120, and the second buried insulating layer 122 in the layout. The first buried insulating layer 114 formed within the second trench T2 inside the etch stop pattern 124 is etched. In the layout, the second trench T2 is placed inside the etch stop pattern 124.

Referring to FIG. 13B, the etch stop pattern 124 is formed on the mold cover layer 108, the first liner layer 110, the second liner layer 112, the third liner layer 120, and the second buried insulating layer 122. The first buried insulating layer 114 within the second trench T2 and the third trench T3 inside the etch stop pattern 124 is etched.

Accordingly, the second liner layer 112 may be exposed by the second trench T2 and the third trench T3. When the first buried insulating layer (114 of FIG. 12B) is etched, the first liner layer 110 and the second liner layer 112 formed at the bottom of the second trench T2 may be etched to expose the substrate 100 as indicated by reference numeral 126.

Referring to FIG. 13C, the etch stop pattern 124 is formed on the mold cover layer 108, the first liner layer 110, the second liner layer 112, the third liner layer 120, and the second buried insulating layer 122. The first buried insulating layer 114 within the second trench T2 and the fourth trench T4 inside the etch stop pattern 124 is etched. Accordingly, the second liner layer 112 may be exposed by the second trench T2 and the fourth trench T4. When the first buried insulating layer 114 is etched, the first liner layer 110 and the second liner layer 112 formed at the bottom of the second trench T2 may be etched to expose the substrate 100 as indicated by reference number 126.

Referring to FIG. 13D, the etch stop pattern 124 is formed on the mold cover layer 108. The first buried insulating layer (114 in FIG. 12D) in the third trench T3 and the fourth trench T4 is etched. Accordingly, the first liner layer 110 and the second liner layer 112 are formed to surround the first channel layer 104 in the third trench T3 and the fourth trench T4.

Referring to FIG. 13E, the etch stop pattern 124 is formed on the mold cover layer 108. Similarly to FIG. 12E, the second buried insulating layer 122 is formed within the third trench T3 and the fourth trench T4. The second buried insulating layer 122 may be formed between the first channel layers 104 in the first horizontal direction (the X direction) and vertical direction (the Z direction).

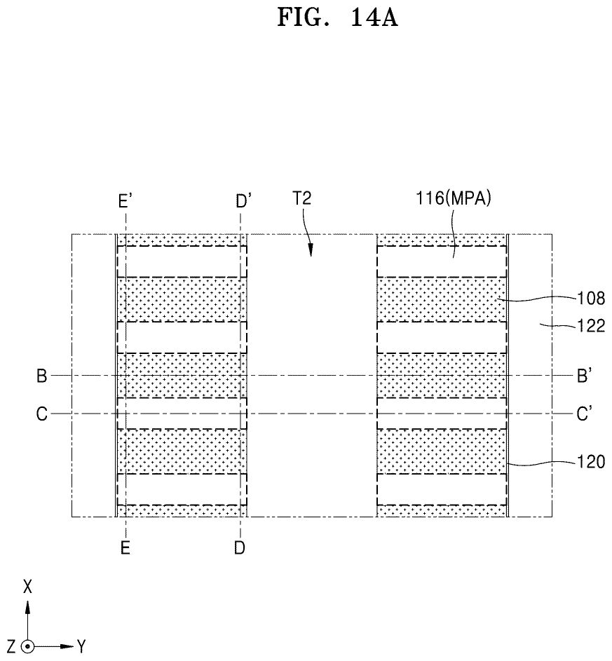

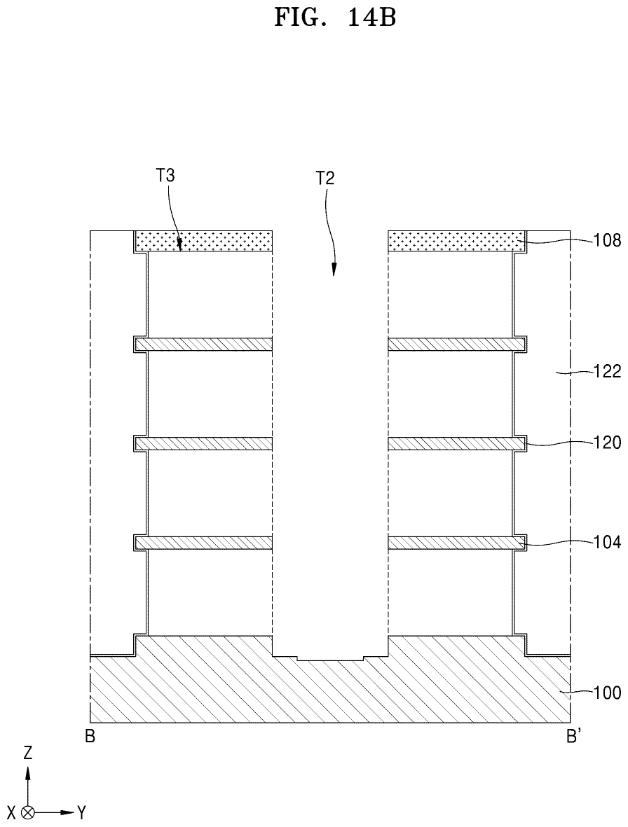

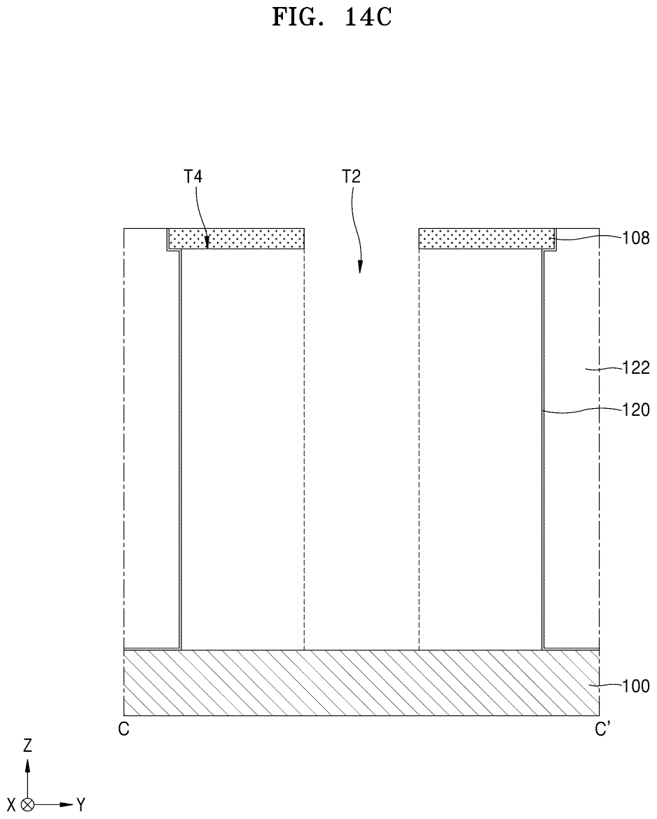

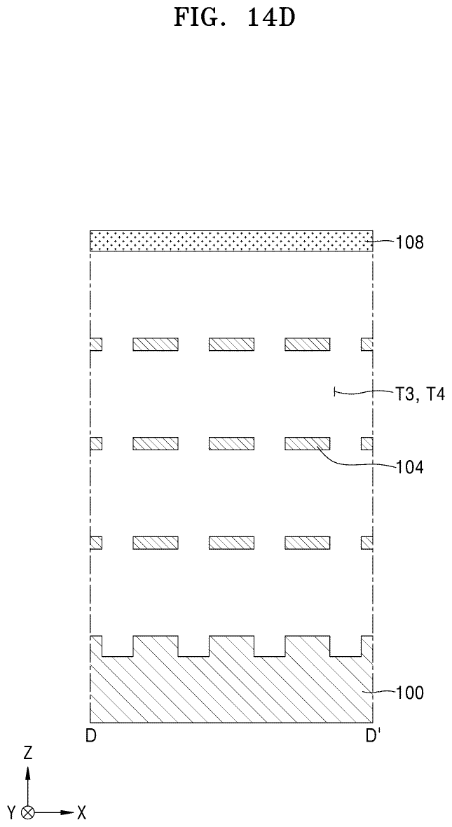

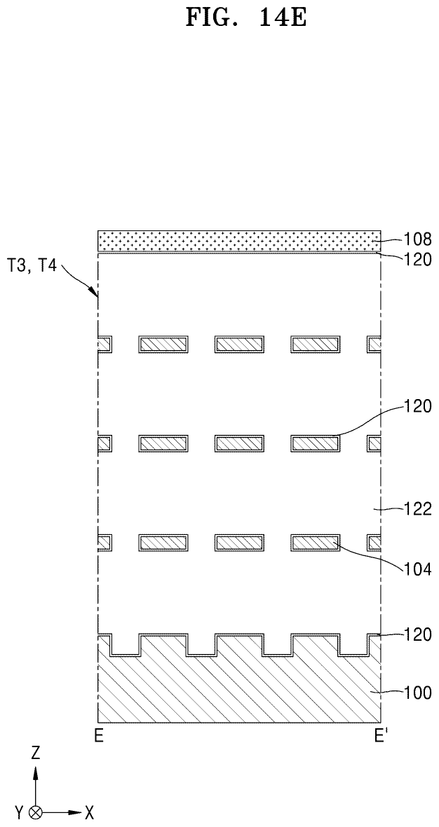

FIGS. 14A, 14B, 14C, 14D, and 14E illustrate etching the etch stop pattern (124 of FIGS. 13A, 13B, 13C, 13D, and 13E) and etching the first liner layer 110 and the second liner layer 112. In detail, the etch stop pattern (124 of FIGS. 13A, 13B, 13C, 13D, and 13E) formed on the mold cover layer 108 is etched, and the first liner layer 110 and the second liner layer 112 within the second trench T2, the third trench T3, and the fourth trench T4 are etched.

Referring to FIG. 14A, in the layout, the etch stop pattern (124 of FIG. 13A) is etched, and the first liner layer (110 of FIG. 13A) and the second liner layer (112 of FIG. 13A) formed on the inner side of the mold pattern MPA and the mold cover layer 108 are etched. In this manner, the second trench T2 may be formed on the inner side of the mold pattern MPA and the mold cover layer 108 in the layout.

Referring to FIG. 14B, the etch stop pattern (124 in FIG. 13B) on the mold cover layer (108 in FIG. 13B) is etched. The first liner layer (110 in FIG. 13B) and the second liner layer (112 in FIG. 13B) in the second trench T2 and the third trench T3 are etched. Accordingly, the third liner layer 120 may be exposed by the second trench T2 and the third trench T3.

Referring to FIG. 14C, the etch stop pattern (124 in FIG. 13C) on the mold cover layer (108 in FIG. 13C) is etched. The first liner layer (110 in FIG. 13C) and the second liner layer (112 in FIG. 13C) in the second trench T2 and the fourth trench T4 are etched. Accordingly, the third liner layer 120 may be exposed by the second trench T2 and the fourth trench T4.

Referring to FIG. 14D, the etch stop pattern (124 in FIG. 13D) on the mold cover layer (108 in FIG. 13D) is etched. The first liner layer (110 in FIG. 13D) and the second liner layer (112 in FIG. 13D) in the third trench T3 and the fourth trench T4 are etched. Accordingly, the surface of the first channel layer 104 may be exposed by the third trench T3 and the fourth trench T4.

Referring to FIG. 14E, the etch stop pattern (124 in FIG. 13E) on the mold cover layer (108 in FIG. 13E) is etched. Similarly to FIG. 13E, the second buried insulating layer 122 is formed within the third trench T3 and the fourth trench T4. The second buried insulating layer 122 may be formed between the first channel layers 104 in the first horizontal direction (the X direction) and vertical direction (the Z direction).

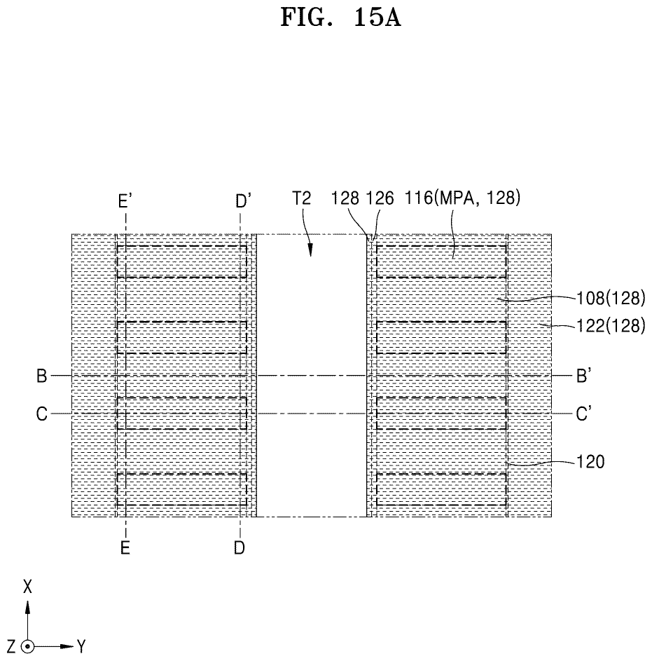

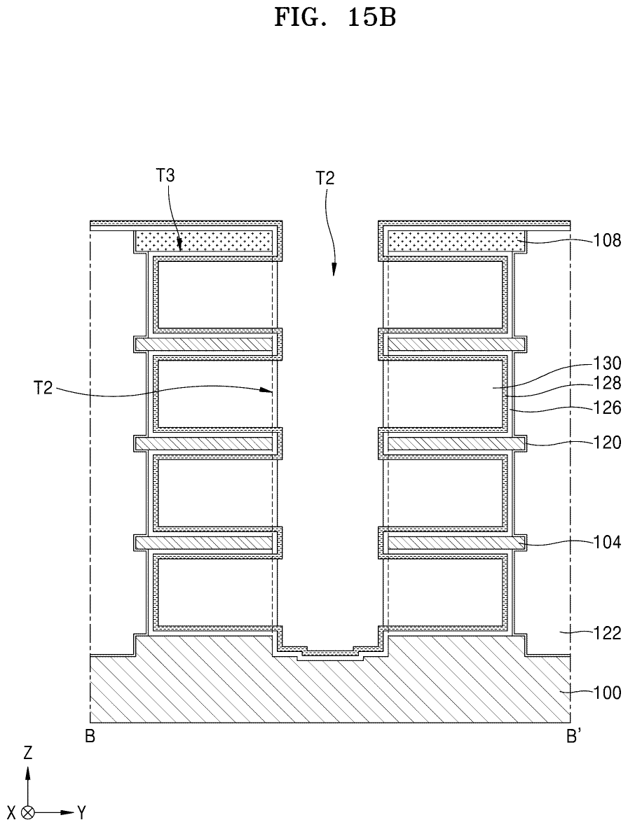

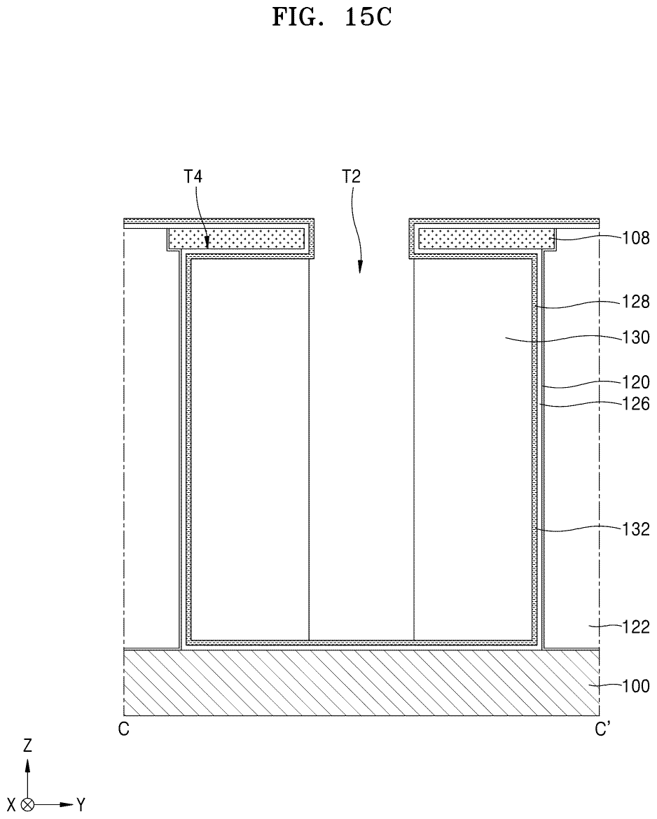

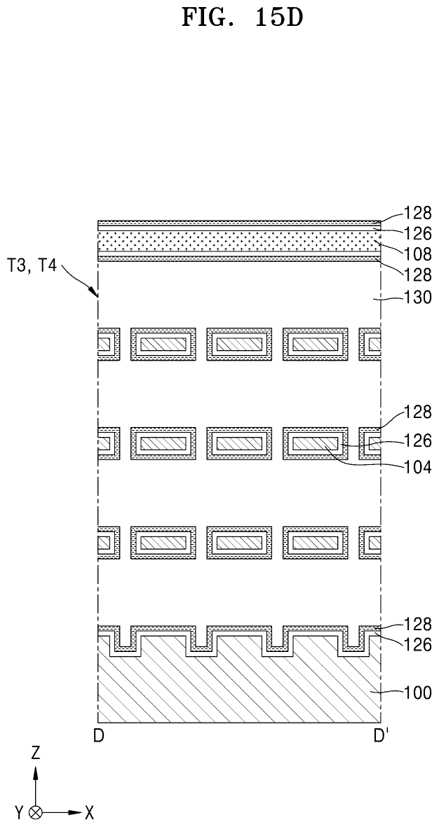

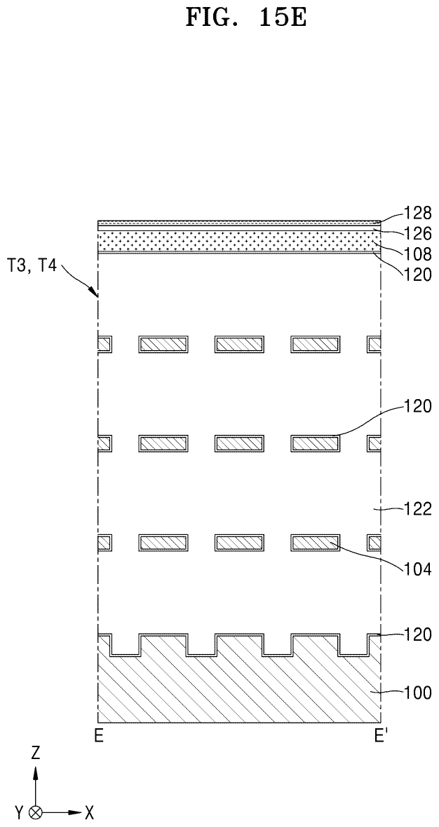

FIGS. 15A, 15B, 15C, 15D, and 15E illustrate forming the first gate insulating layer 126, a fourth liner layer 128, and a third buried insulating pattern 130.

In detail, the first gate insulating layer 126 and the fourth liner layer 128 are formed on one sidewall of the third trench T3 and the fourth trench T4 and on the surface of the first channel layer 104. In some implementations, the first gate insulating layer 126 may include, but is not limited to, silicon oxide (SiO₂), aluminum oxide (AlO), hafnium oxide (HfO), zirconium oxide (ZrO), lanthanum oxide (LaO), or the like. In some implementations, the fourth liner layer 128 may include silicon nitride.

The fourth liner layer 128 is provided for the formation of a channel layer and storage node in a subsequent process. The third buried insulating pattern 130 is formed to fill the inside of the third trench T3 and the fourth trench T4. In some implementations, the third buried insulating pattern 130 may include silicon oxide.

Referring to FIG. 15A, the first gate insulating layer 126 and the fourth liner layer 128 are formed on the inner side of the mold pattern MPA and the mold cover layer 108 in the layout. In the layout, the first gate insulating layer 126 and the fourth liner layer 128 are formed on one sidewall of the second trench T2.

Referring to FIG. 15B, the first gate insulating layer 126 and the fourth liner layer 128 are formed on one sidewall of the third trench T3 and the surface of the first channel layer 104. The first gate insulating layer 126 and the fourth liner layer 128 may be formed on the upper and lower surfaces of the first channel layer 104.

The third buried insulating pattern 130 is formed to fill the inside of the third trench T3. The third buried insulating pattern 130 may be formed by forming an insulating layer to fill the inside of the second trench T2 and the third trench T3 and then performing etching.

Referring to FIG. 15C, the first gate insulating layer 126 and the fourth liner layer 128 are formed on one sidewall of the fourth trench T4. The third buried insulating pattern 130 is formed to fill the inside of the fourth trench T4. The third buried insulating pattern 130 may be formed by forming an insulating layer to fill the inside of the fourth trench T4 and then performing etching.

Referring to FIG. 15D, the first gate insulating layer 126 and the fourth liner layer 128 are formed to surround the first channel layer 104. In addition, the first gate insulating layer 126 and the fourth liner layer 128 are formed on the mold cover layer 108. The third buried insulating pattern 130 is formed to fill the inside of the third trench T3 and the fourth trench T4.

Referring to FIG. 15E, the first gate insulating layer 126 and the fourth liner layer 128 are formed on the mold cover layer 108. Similarly to FIG. 14E, the second buried insulating layer 122 is formed within the third trench T3 and the fourth trench T4. The second buried insulating layer 122 may be formed between the first channel layers 104 in the first horizontal direction (the X direction) and vertical direction (the Z direction).

FIGS. 16A, 16B, 16C, 16D, 16E, and 16F illustrate forming the fourth liner pattern 132, the storage node 134, and the second channel layer 136. In detail, the storage node 134 and the second channel layer 136 are formed on the upper and lower portions of the third trench T3, the upper and lower portions of the fourth trench T4, and the upper and lower surfaces of the first gate insulating layer 126.

The fourth liner layer 128 is recess-etched in the second horizontal direction (the Y direction) on one sidewall of the mold cover layer 108 to form a horizontal trench (T5 in FIG. 16F) within the third buried insulating pattern 130. The storage node 134 and the second channel layer 136 are formed within the horizontal trench (T5 in FIG. 16F).

Referring to FIG. 16A, the first gate insulating layer 126 formed on the inner side of the mold pattern MPA and the mold cover layer 108 is arranged in the layout. In the layout, the first gate insulating layer 126 is arranged on the mold pattern MPA, the mold cover layer 108, the third liner layer 120, and the second buried insulating layer 122. The second trench T2 is arranged on the inner side of the mold pattern MPA and the mold cover layer 108.

Referring to FIGS. 16B and 16F, the storage node 134 and the second channel layer 136 are formed on the upper and lower portions of the third trench T3 and the upper and lower surfaces of the first gate insulating layer 126.

In some implementations, the second channel layer 136 may include at least one of an oxide semiconductor, polysilicon, a 2D material semiconductor, or combinations thereof. In some implementations, the second channel layer 136 may include a depositable material, such as silicon or an oxide semiconductor (e.g., indium gallium zinc oxide (IGZO).

In some implementations, the storage node 134 may include a conductive material. The storage node 134 may include a metal material, such as titanium nitride, tungsten, ruthenium, molybdenum, etc. In some implementations, the storage node 134 may include polysilicon.

The fourth liner layer 128 is recess-etched in the second horizontal direction (the Y direction) on one sidewall of the mold cover layer 108 to form the horizontal trench (T5 in FIG. 16F) within the third buried insulating pattern 130. The fourth liner layer 128 may be recess-etched to form the fourth liner pattern 132 inside the first gate insulating layer 126 within the third trench T3.

The storage node 134 and the second channel layer 136 are formed within the horizontal trench (T5 in FIG. 16F). In some implementations, the storage node 134 and the second channel layer 136 may not fully fill the horizontal trench (T5 of FIG. 16F), as indicated by reference numeral T5r.

Referring to FIG. 16C, the storage node 134 and the second channel layer 136 are formed above and below the fourth trench T4. The fourth liner layer 128 is recess-etched in the second horizontal direction (the Y direction) on one sidewall of the mold cover layer 108 to form a horizontal trench within the third buried insulating pattern 130.

The fourth liner layer 128 may be recess-etched to form the fourth liner pattern 132 inside the first gate insulating layer 126 within the fourth trench T4. The storage node 134 and the second channel layer 136 are formed within the horizontal trench. In some implementations, the storage node 134 and the second channel layer 136 may not fully fill the horizontal trench.

Referring to FIG. 16D, the fourth liner layer 128 formed on the first gate insulating layer 126 on the first channel layer 104 in the third trench T3 and the fourth trench T4 is etched.

The second channel layer 136 is formed to surround the first gate insulating layer 126 on top of the first channel layer 104 in the third trench T3 and the fourth trench T4. The second channel layer 136 may be formed within the third buried insulating pattern 130. In addition, the fourth liner layer (128 in FIG. 15D) formed on the first gate insulating layer 126 above the mold cover layer 108 is etched.

Referring to FIG. 16E, the fourth liner layer (128 of FIG. 15E) formed on the first gate insulating layer 126 on the mold cover layer 108 is etched. Similarly to FIG. 15E, the second buried insulating layer 122 is formed within the third trench T3 and the fourth trench T4. The second buried insulating layer 122 may be formed between the first channel layers 104 in the first horizontal direction (the X direction) and vertical direction (the Z direction).

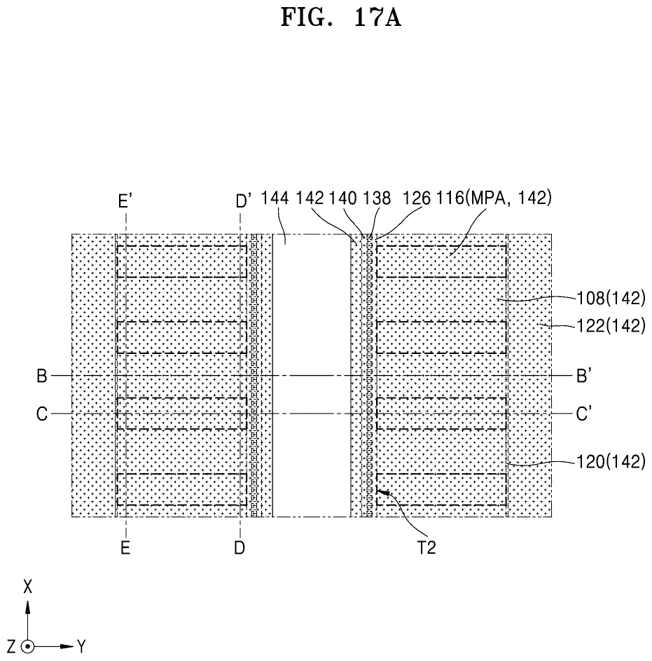

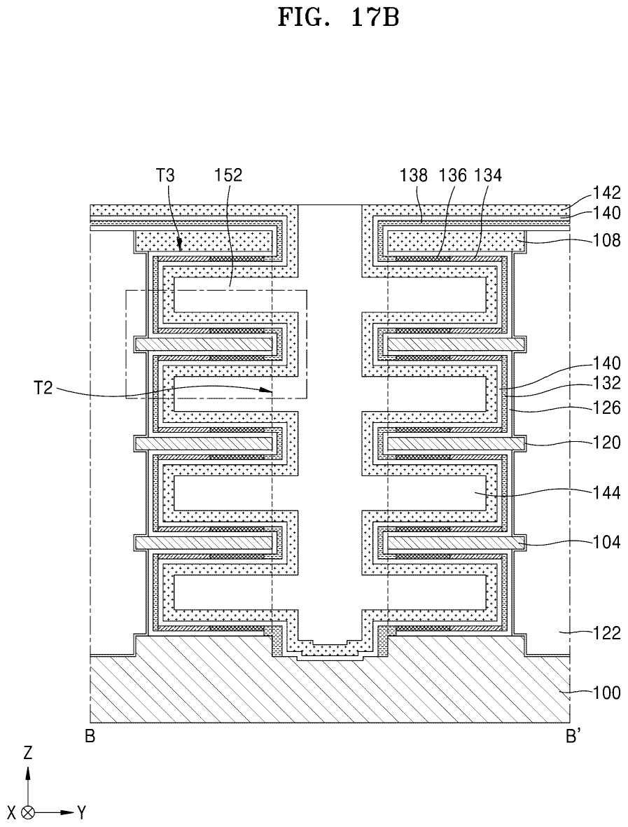

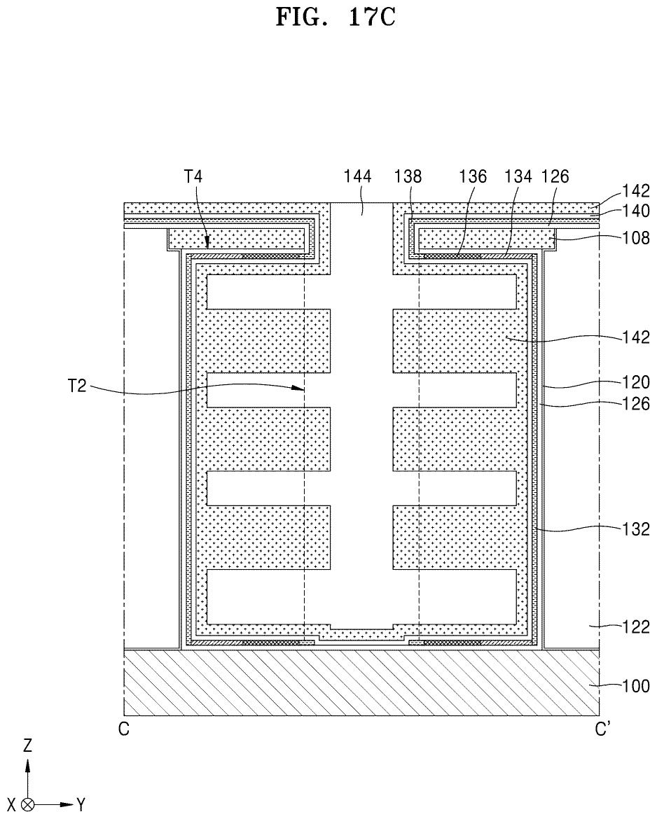

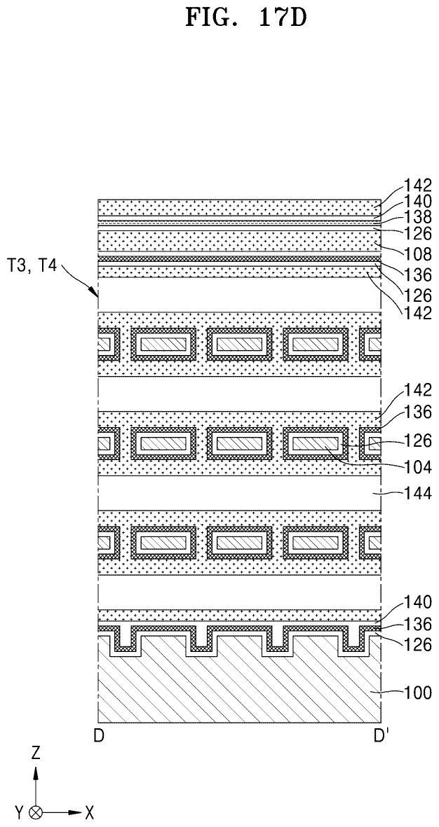

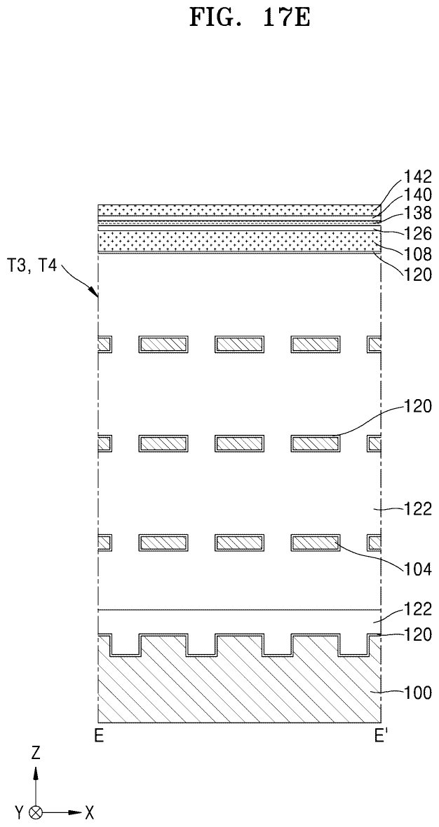

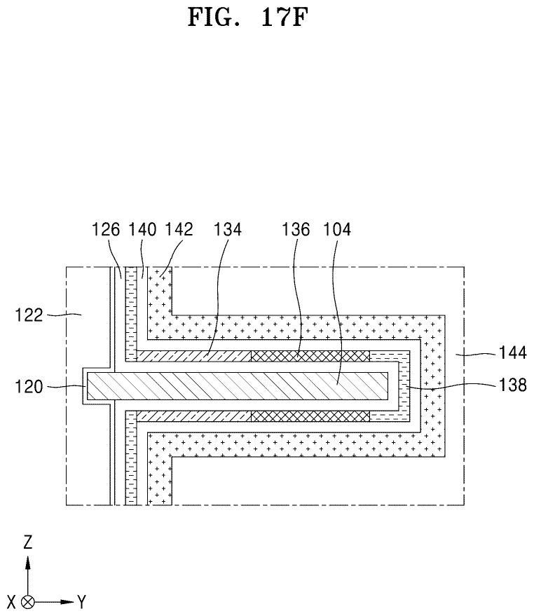

FIGS. 17A, 17B, 17C, 17D, 17E, and 17F illustrate forming the first capping insulating layer 138, the second gate insulating layer 140, a fifth liner layer 142, and a fourth buried insulating layer 144.

In detail, the first capping insulating layer 138 is formed to cover one sidewall of the second channel layer 136 and the first gate insulating layer 126 above one sidewall of the first channel layer 104. In some implementations, the first capping insulating layer 138 may include silicon oxide. The first capping insulating layer 138 may also be formed on the first gate insulating layer 126 of the sidewall and surface of the mold cover layer 108.

The third buried insulating pattern 130 inside the second trench T2, the third trench T3, and the fourth trench T4 is etched. The second gate insulating layer 140 is formed on the fourth liner pattern 132, the storage node 134, the second channel layer 136, and the first capping insulating layer 138 within the third trench T3 and the fourth trench T4. In some implementations, the second gate insulating layer 140 may include the same material as that of the first gate insulating layer 126.

The fifth liner layer 142 is formed on the second gate insulating layer 140 inside the third trench T3 and the fourth trench T4. In some implementations, the fifth liner layer 142 may include silicon nitride. The fourth buried insulating layer 144 is formed inside the second trench T2, the third trench T3, and the fourth trench T4. In some implementations, the fourth buried insulating layer 144 may include silicon oxide.

Referring to FIG. 17A, the first gate insulating layer 126, the second gate insulating layer 140, and the fifth liner layer 142 are arranged on the inner side of the mold pattern MPA and the mold cover layer 108 in the layout. The first gate insulating layer 126, the second gate insulating layer 140, and the fifth liner layer 142 are arranged on one sidewall of the second trench T2 placed on the inner side of the mold pattern MPA and the mold cover layer 108. The fourth buried insulating layer 144 is placed inside the second trench T2.

Referring to FIGS. 17B and 17F, the first capping insulating layer 138 is formed to cover one sidewall of the second channel layer 136 and the first gate insulating layer 126 above one sidewall of the first channel layer 104 within the second trench T2 and the third trench T3. The first capping insulating layer 138 may also be formed on the first gate insulating layer 126 of the sidewall and surface of the mold cover layer 108.

The third buried insulating pattern 130 inside the second trench T2 and the third trench T3 is etched. The second gate insulating layer 140 is formed on the fourth liner pattern 132, the storage node 134, the second channel layer 136, and the first capping insulating layer 138 within the third trench T3. The fifth liner layer 142 is formed on the second gate insulating layer 140 inside the second trench and the third trench T3. The fourth buried insulating layer 144 is formed inside the second trench T2 and the third trench T3.

Referring to FIG. 17C, the first capping insulating layer 138 is formed to cover one sidewall of the second channel layer 136 within the second trench T2 and the fourth trench T4. The first capping insulating layer 138 may also be formed on the first gate insulating layer 126 of the sidewall and surface of the mold cover layer 108.

The third buried insulating pattern 130 inside the second trench T2 and the fourth trench T4 is etched. The second gate insulating layer 140 is formed on the fourth liner pattern 132, the storage node 134, the second channel layer 136, and the first capping insulating layer 138 within the fourth trench T4.

The fifth liner layer 142 is formed on the second gate insulating layer 140 inside the second trench T2 and the fourth trench T4. The fifth liner layer 142 may be formed on one sidewall of the second gate insulating layer 140 within the fourth trench T4. In addition, the fifth liner layers 142 may be formed apart from each other in the vertical direction (the Z direction) within the second trench T2 and the fourth trench T4. Subsequently, the fourth buried insulating layer 144 is formed inside the second trench T2 and the fourth trench T4.

Referring to FIG. 17D, the first capping insulating layer 138 may be formed on the first gate insulating layer 126 above the mold cover layer 108. The third buried insulating pattern (130 in FIG. 16D) inside the third trench T3 and the fourth trench T4 is etched.

The second gate insulating layer 140 and the fifth liner layer 142 are formed on the second channel layer 136 inside the third trench T3 and the fourth trench T4. The second gate insulating layer 140 and the fifth liner layer 142 may also be formed on the first capping insulating layer 138 above the mold cover layer 108.

The fifth liner layer 142 is formed to surround the second channel layer 136 within the third trench T3 and the fourth trench T4. Subsequently, the fourth buried insulating layer 144 is formed inside the third trench T3 and the fourth trench T4.

Referring to FIG. 17E, the first capping insulating layer 138, the second gate insulating layer 140, and the fifth liner layer 142 are formed on the first gate insulating layer 126 on the mold cover layer 108. Similarly to FIG. 16E, the second buried insulating layer 122 is formed within the third trench T3 and the fourth trench T4. The second buried insulating layer 122 may be formed between the first channel layers 104 in the first horizontal direction (the X direction) and vertical direction (the Z direction).

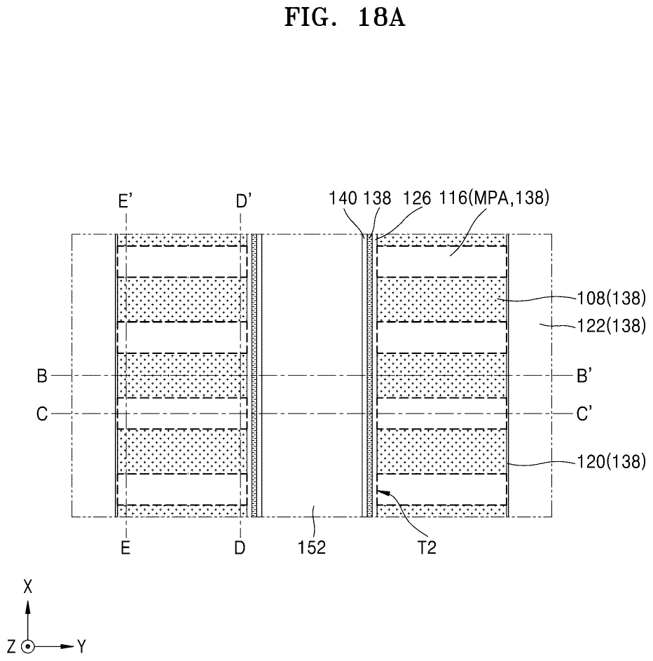

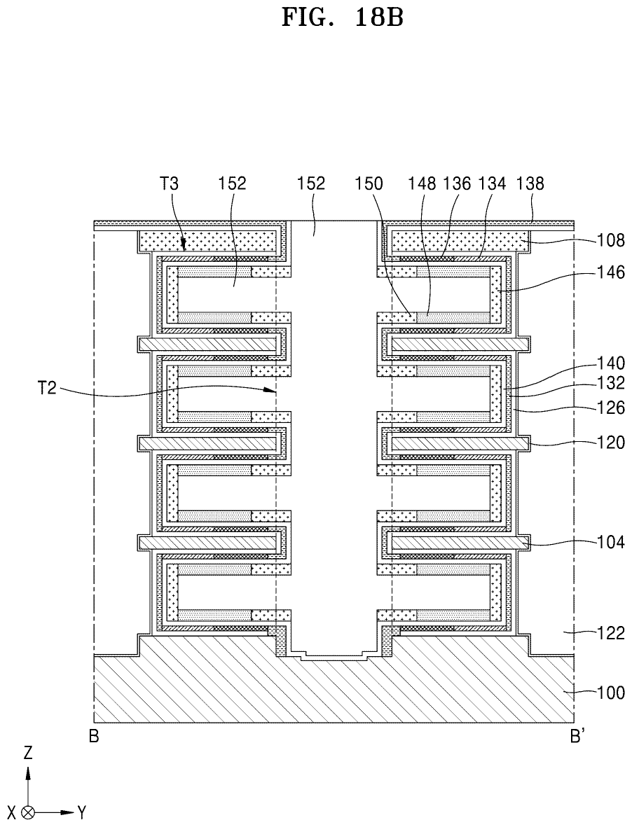

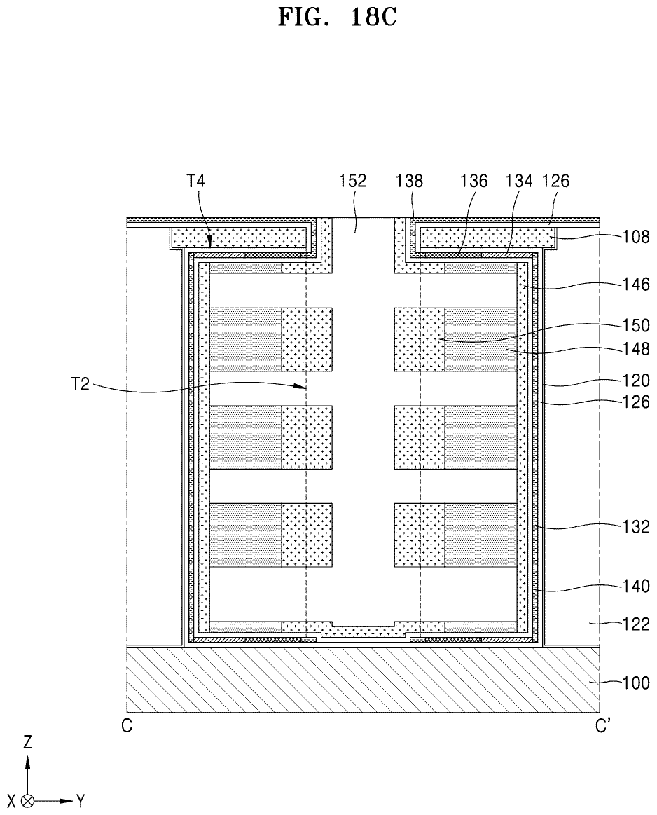

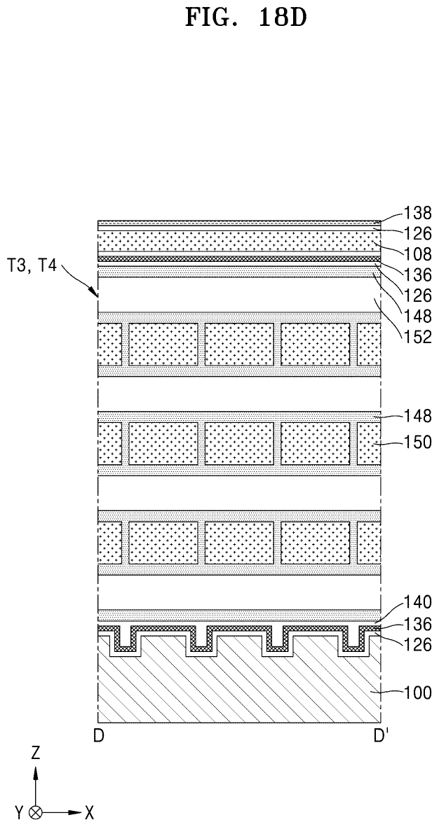

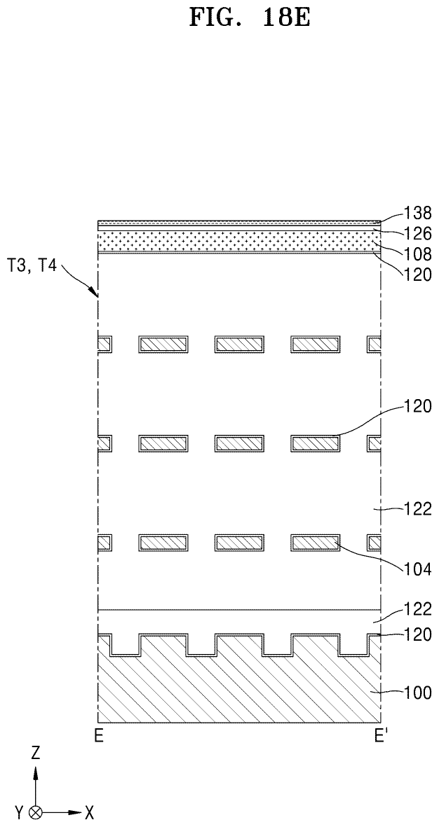

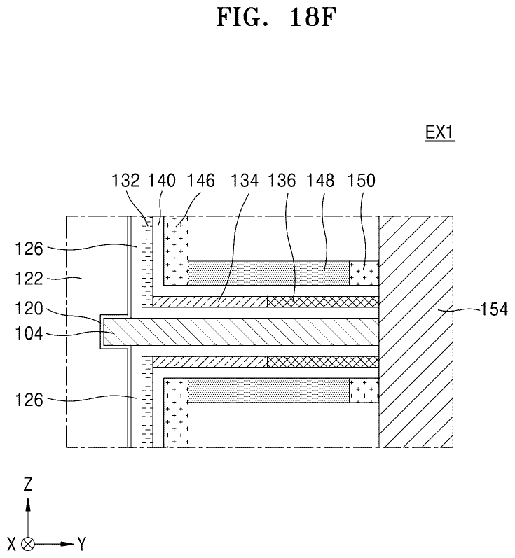

FIGS. 18A, 18B, 18C, 18D, 18E, and 18F illustrate etching and removing the fourth buried insulating layer 144 and forming the fifth liner pattern 146, the word line 148, the second capping insulating pattern 150, and the fifth buried insulating layer 152.

In detail, after the fifth liner layer (142 of FIGS. 17A, 17B, 17C, 17D, and 17E) and the second gate insulating layer 140 above the mold cover layer 108 are etched, the fourth buried insulating layer (144 of FIGS. 17A, 17B, 17C, 17D, and 17E) formed in the second trench T2, the third trench T3, and the fourth trench T4 is etched and removed.

The fifth liner layer (142 of FIGS. 17A, 17B, 17C, 17D, and 17E) formed in the second trench T2, the third trench T3, and the fourth trench T4 is etched in the second horizontal direction (the Y direction) to form the fifth liner pattern 146 on one sidewall of the second gate insulating layer 140. The word line 148 is formed on the second gate insulating layer 140 above and below the first channel layer 104 in the third trench T3. In the fourth trench T4, word lines 148 are formed apart from each other in the vertical direction (the Z direction). In some implementations, the word line 148 may include a metallic material, such as titanium nitride (TiN), tungsten (W), molybdenum (Mo) but is not limited thereto.

The second capping insulating pattern 150 is formed on one sidewall of the word line 148 above and below the first channel layer 104 in the third trench T3. In some implementations, the second capping insulating pattern 150 may include silicon nitride. The second capping insulating pattern 150 is formed on one sidewall of the word lines 148 apart from each other in the vertical direction (the Z direction) within the fourth trench T4. The fifth buried insulating layer 152 is formed inside the second trench T2, the third trench T3, and the fourth trench T4. In some implementations, the fifth buried insulating layer 152 may include silicon oxide.

Referring to FIG. 18A, the first gate insulating layer 126, the first capping insulating layer 138, and the second gate insulating layer 140 are arranged on the inner side of the mold pattern MPA and the mold cover layer 108 in the layout. The first gate insulating layer 126, the first capping insulating layer 138, and the second gate insulating layer 140 are arranged on one sidewall of the second trench T2 placed on the inner side of the mold pattern MPA and the mold cover layer 108. The fourth buried insulating layer 144 is placed inside the second trench T2.

Referring to FIGS. 18B and 18F, after the fourth liner layer (142 of FIG. 17B) and the second gate insulating layer (140 of FIG. 17B) above the mold cover layer 108 are etched, the fourth buried insulating layer (144 of FIG. 17B) formed in the second trench T2 and the third trench T3 is etched and removed.

The fifth liner layer (142 of FIGS. 17A, 17B, 17C, 17D, and 17E) formed in the second trench T2 and the third trench T3 is etched in the second horizontal direction (the Y direction) to form the fifth liner pattern 146 on one sidewall of the second gate insulating layer 140. The word line 148 is formed on the second gate insulating layer 140 above and below the first channel layer 104 in the third trench T3.

The second capping insulating pattern 150 is formed on one sidewall of the word line 148 above and below the first channel layer 104 in the third trench T3. The fifth buried insulating layer 152 is formed inside the second trench T2 and the third trench T3.

Referring to FIG. 18C, after the fourth liner layer (142 of FIG. 17C) and the second gate insulating layer (140 of FIG. 17C) above the mold cover layer 108 are etched, the fourth buried insulating layer (144 of FIGS. 17A, 17B, 17C, 17D, and 17E) formed in the second trench T2 and the fourth trench T4 is etched and removed.

The fifth liner layer (142 in FIG. 17C) formed in the second trench T2 and the fourth trench T4 is etched in the second horizontal direction (the Y direction) to form the fifth liner pattern 146 on one sidewall of the second gate insulating layer 140. The word lines 148 are formed apart from each other in the vertical direction (the Z direction) within the fourth trench T4. The second capping insulating pattern 150 is formed on one sidewall of the word lines 148 apart from each other in the vertical direction (the Z direction) within the fourth trench T4. The fifth buried insulating layer 152 is formed inside the second trench T2 and the fourth trench T4.

Referring to FIG. 18D, after the fourth liner layer (142 of FIG. 17D) and the second gate insulating layer (140 of FIG. 17D) above the mold cover layer 108 are etched, the fourth buried insulating layer (144 of FIG. 17D) formed in the third trench T3 and the fourth trench T4 is etched and removed.

The word line 148 is formed within the third trench T3 and the fourth trench T4. The word lines 148 extend in the first horizontal direction (the X direction) and are connected to each other in the vertical direction (the Z direction). The word line 148 may be formed in a shape that surrounds the first channel layer (104 in FIG. 18B). The second capping insulating pattern 150 is formed between the word lines 148. Subsequently, the fifth buried insulating layer 152 is formed inside the second trench T2 and the fourth trench T4.

Referring to FIG. 18E, the fourth liner layer (142 of FIG. 17E) and the second gate insulating layer (140 of FIG. 17E) above the mold cover layer 108 are etched. Similarly to FIG. 17E, the second buried insulating layer 122 is formed within the third trench T3 and the fourth trench T4. The second buried insulating layer 122 may be formed between the first channel layers 104 in the first horizontal direction (the X direction) and vertical direction (the Z direction).

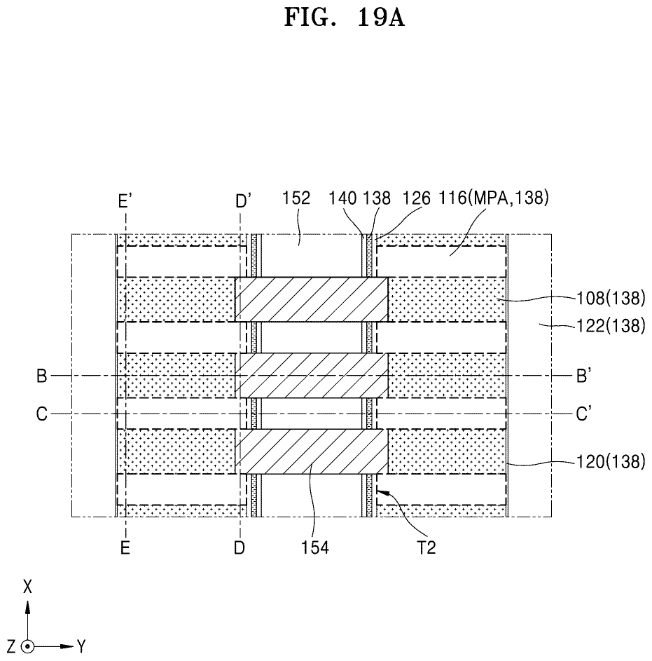

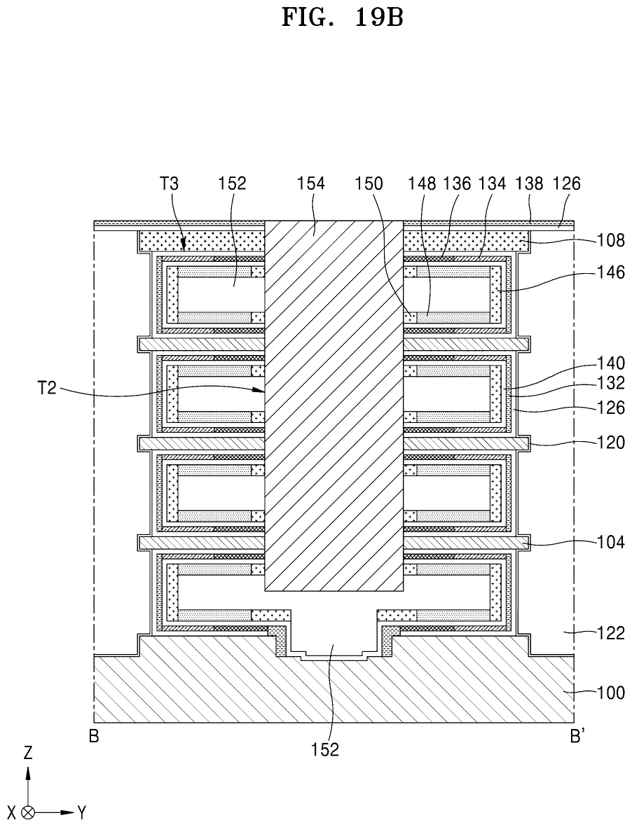

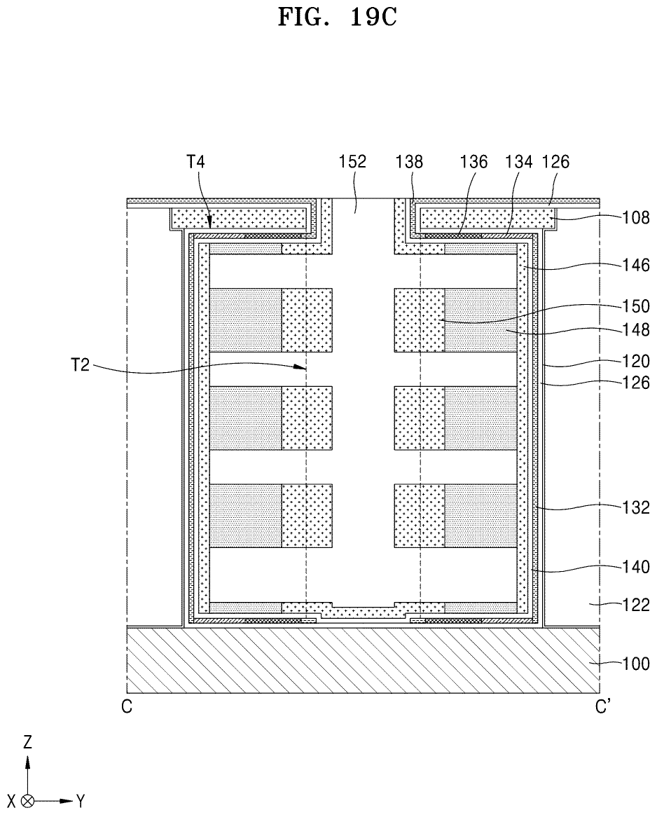

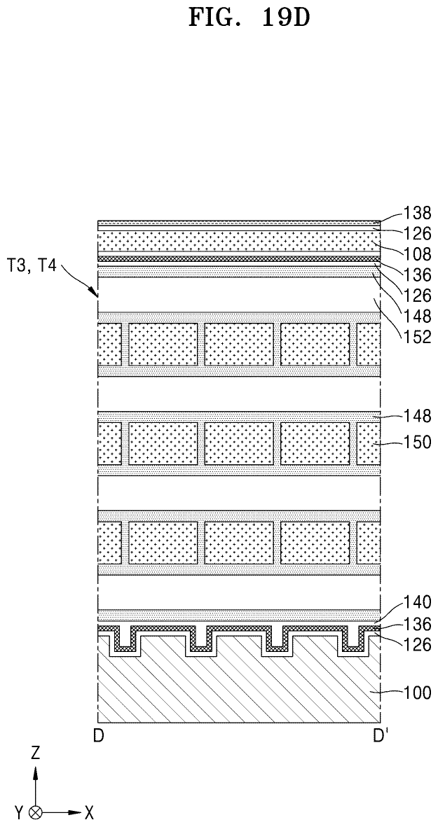

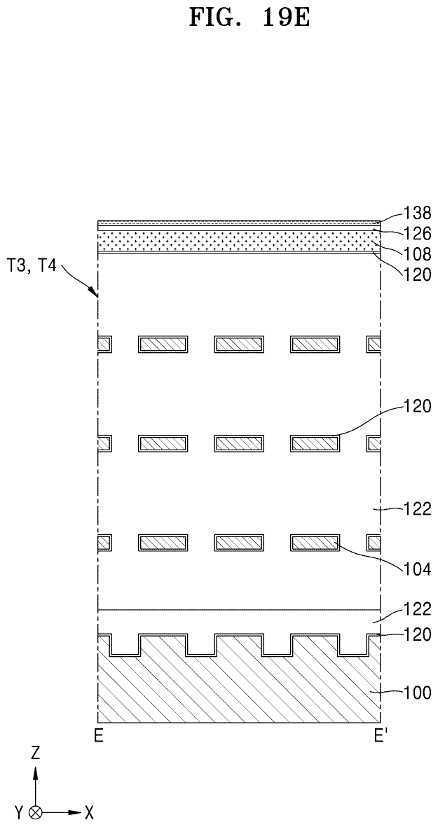

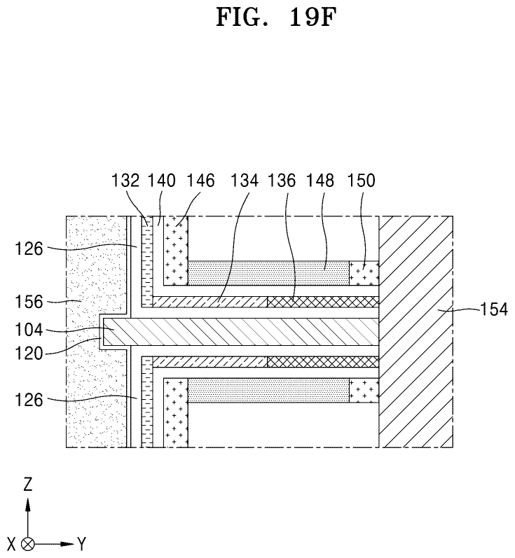

FIGS. 19A, 19B, 19C, 19D, 19E, and 19F include forming the bit lines 154 extending in the second horizontal direction (the Y direction) and apart in the first horizontal direction in the layout.

In detail, the first gate insulating layer 126, the first capping insulating layer 138, the second gate insulating layer 140, the second capping insulating pattern 150, and the fifth buried insulating layer 152 within the second trench T2 are etched. The bit line 154 is formed within the second trench T2.

The bit line 154 may contact one side of the first channel layer 104, the first gate insulating layer 126, the second channel layer 136, the second gate insulating layer 140, and the second capping insulating pattern 150 in the vertical direction (the Z direction). In some implementations, the bit line 154 may include a conductive material. The bit line 154 may include doped polysilicon or the metal material as described above.

Referring to FIG. 19A, the bit line 154 is arranged in the second trench T2 on the inner side of the mold cover layer 108 in the layout. The bit lines 154 are arranged to extend in the second horizontal direction (the Y direction) and apart in the first horizontal direction in the layout.

Referring to FIGS. 19B and 19F, the first gate insulating layer 126, the first capping insulating layer 138, the second gate insulating layer 140, the second capping insulating pattern 150, and the fifth buried insulating layer 152 within the second trench T2 are etched in the vertical direction (the Z direction). In some implementations, the fifth buried insulating layer 152 may not be fully etched in the vertical direction but may remain partially such that the substrate 100 is not exposed.

The bit line 154 is formed within the second trench T2. The bit line 154 may contact one side of the first channel layer 104, the first gate insulating layer 126, the second channel layer 136, the second gate insulating layer 140, and the second capping insulating pattern 150 in the vertical direction (the Z direction).

Referring to FIG. 19C, the structure may be the same as that of FIG. 18C. The fifth liner pattern 146 is formed on one sidewall of the second gate insulating layer 140. The Word lines 148 are formed apart from each other in the vertical direction (the Z direction) within the fourth trench T4. The second capping insulating pattern 150 is formed on one sidewall of the word lines 148 apart from each other in the vertical direction (the Z direction) within the fourth trench T4. The fifth buried insulating layer 152 is formed inside the second trench T2 and the fourth trench T4.

Referring to FIG. 19D, the structure may be the same as that of FIG. 18D. The word line 148 is formed within the third trench T3 and the fourth trench T4. The word lines 148 extend in the first horizontal direction (the X direction) and are connected to each other in the vertical direction (the Z direction). The word line 148 may be formed in a shape that surrounds the first channel layer (104 in FIG. 18B). The second capping insulating pattern 150 is formed between the word lines 148. Subsequently, the fifth buried insulating layer 152 is formed inside the second trench T2 and the fourth trench T4.

Referring to FIG. 19E, the second buried insulating layer 122 is formed within the third trench T3 and the fourth trench T4, similarly to FIG. 18E. The second buried insulating layer 122 may be formed between the first channel layers 104 in the first horizontal direction (the X direction) and vertical direction (the Z direction).

Subsequently, the manufacturing process of FIGS. 2A, 2B, 2C, 2D, 2E, 2F, 2G to 2H is performed. FIGS. 2A, 2B, 2C, 2D, 2E, 2F, 2G to 2H include forming the ground electrode 156 extending in the first horizontal direction (the X direction) in the layout.

In detail, the first gate insulating layer (126 of FIG. 19B), the first capping insulating layer (138 of FIG. 19B), and the second buried insulating layer (122 of FIG. 19B) located on the outer side of the mold cover layer 108 and the outer side of the first channel layer 104 are etched. The third liner layer (120 in FIG. 19B) formed at one end of the first channel layer 104 may be exposed as the second buried insulating layer (122 in FIG. 19B) is etched.

The third liner layer (120 in FIG. 19B) exposed at one end of the first channel layer 104 is etched. After silicide is formed at one end of the first channel layer 104, the ground electrode 156 is formed on one side of the first channel layer 104 and the first gate insulating layer 126. The ground electrode 156 may include a conductive material. The ground electrode 156 may include a metal material, such as titanium nitride, tungsten, molybdenum, or ruthenium.

Referring to FIG. 2A, the ground electrode 156 extending in the first horizontal direction (the X direction) is formed on the outer side of the mold cover layer 108 in the layout.

Referring to FIGS. 2B and 2H, the first gate insulating layer (126 of FIG. 19B), the first capping insulating layer (138 of FIG. 19B), and the second buried insulating layer (122 of FIG. 19B) located on the outer side of the mold cover layer 108 and the outer side of the first channel layer 104 are etched. The second buried insulating layer (122 in FIG. 19B) located outside the third trench T3 is etched. The third liner layer (120 in FIG. 19B) formed at one end of the first channel layer 104 may be exposed as the second buried insulating layer (122 in FIG. 19B) is etched.

The third liner layer (120 in FIG. 19B) exposed at one end of the first channel layer 104 is removed by etching. After forming silicide at one end of the first channel layer 104, the ground electrode 156 is formed on one side of the first channel layer 104 and the first gate insulating layer 126. The ground electrode 156 may be formed in the vertical direction (the Z direction).

Referring to FIG. 2C, the first gate insulating layer (126 of FIG. 19C), the first capping insulating layer (138 of FIG. 19C), and the second buried insulating layer (122 of FIG. 19C) located on the outer side of the mold cover layer (108 of FIG. 19C) are etched. The second buried insulating layer (122 in FIG. 19C) located outside the fourth trench T4 is etched. One side of the first gate insulating layer 126 may be exposed as the second buried insulating layer (122 in FIG. 19C) is etched.

The ground electrode 156 is formed on one side of the exposed first gate insulating layer 126. The ground electrode 156 may be formed in the vertical direction (the Z direction). The third liner layer (120 in FIG. 19B) exposed at one end of the first channel layer 104 is removed by etching.

Referring to FIG. 2D, the structure may be the same as that of FIG. 19D. The word line 148 is formed outside the third trench T3. The word lines 148 extend in the first horizontal direction (the X direction) and are connected to each other in the vertical direction (the Z direction). The word line 148 may be formed in a shape that surrounds the first channel layer (104 in FIG. 18B). The second capping insulating pattern 150 is formed between the word lines 148. Subsequently, the fifth buried insulating layer 152 is formed inside the second trench T2 and the fourth trench T4.

Referring to FIG. 2E, the second buried insulating layer (122 of FIG. 19E) located outside the third trench T3 and the fourth trench T4 is etched. The third liner layer (120 in FIG. 19E) surrounding the first channel layer 104 is etched and removed. The ground electrode 156 is formed outside the third trench T3 and the fourth trench T4.

Referring to FIGS. 2F and 2G, the first gate insulating layer 126 may be formed to surround the first channel layer 104 in the vertical direction (the Z direction). The second channel layer 136 and the storage node 134 may be formed to surround the first gate insulating layer 126. The second gate insulating layer 140 may be formed to surround the second channel layer 136 and the storage node 134. The word line 148 may be formed to surround the second gate insulating layer 140. The fifth buried insulating layer 152 may be formed above and below the word line 148.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various changes in form and details may be made therein without departing from the spirit and scope of the following claims.

What is claimed is:

1. A semiconductor memory device comprising:
a plurality of memory cells arranged three-dimensionally on a substrate in a first horizontal direction, a second horizontal direction orthogonal to the first horizontal direction, and a vertical direction perpendicular to the first horizontal direction and the second horizontal direction, each of the plurality of memory cells including a first transistor including a first channel layer and a second transistor including a second channel layer above and below the first channel layer;
a bit line connected to a first end portion of the first channel layer and extending in the vertical direction;
a ground electrode connected to a second end portion of the first channel layer and extending in the vertical direction;
a storage node above and below the first channel layer and in contact with a first surface of the second channel layer, the second channel layer and the storage node surrounding the first channel layer between the bit line and the ground electrode; and
a word line surrounding the storage node and the second channel layer between the bit line and the ground electrode.

2. The semiconductor memory device of claim 1, wherein the first transistor comprises a read transistor and the second transistor comprises a write transistor.

3. The semiconductor memory device of claim 1, wherein the first transistor comprises a PMOS transistor and the second transistor comprises an NMOS transistor.

4. The semiconductor memory device of claim 1, wherein a second surface of the second channel layer, opposite to the first surface, is in contact with the bit line.

5. The semiconductor memory device of claim 1, wherein a first gate insulating layer is between the first channel layer and the storage node and between the first channel layer and the second channel layer.

6. The semiconductor memory device of claim 1, wherein a second gate insulating layer is between the second channel layer and the word line and between the storage node and the word line.

7. The semiconductor memory device of claim 1, wherein the first channel layer comprises crystalline silicon.

8. The semiconductor memory device of claim 1, wherein the second channel layer comprises at least one of an oxide semiconductor, polysilicon, or a 2D material semiconductor.

9. The semiconductor memory device of claim 1, wherein the storage node is a floating gate of the first transistor.

10. A semiconductor memory device comprising:
a first channel layer extending in a second horizontal direction on a substrate and apart in a first horizontal direction perpendicular to the second horizontal direction, the first channel layer having a first surface and a second surface opposite to the first surface in the second horizontal direction;
a second channel layer above and below the first channel layer, the second channel layer having a first surface and a second surface opposite to the first surface in the second horizontal direction;
a storage node disposed above and below the first channel layer and in contact with the first surface of the second channel layer and disposed inwardly relative to the first surface of the first channel layer in the second horizontal direction;
a bit line contacting a first end portion of each of the first channel layer and the second channel layer in a vertical direction perpendicular to the first horizontal direction and the second horizontal direction;
a ground electrode in contact with a second end portion of the first channel layer in the vertical direction; and
a word line above the second channel layer and the storage node between the bit line and the ground electrode,
wherein the second channel layer and the storage node surround the first channel layer, and the word line surrounds the second channel layer and the storage node.

11. The semiconductor memory device of claim 10, comprising a first transistor and a second transistor,
wherein the first transistor comprises the first channel layer and the word line, and the second transistor comprises the second channel layer and the word line.

12. The semiconductor memory device of claim 11, wherein the first transistor comprises a read transistor and the second transistor comprises a write transistor.

13. The semiconductor memory device of claim 10, wherein the word line surrounds both the storage node and the second channel layer.

14. The semiconductor memory device of claim 10, further comprising a work function adjustment layer in contact with the word line on the second channel layer on one side of the word line.

15. The semiconductor memory device of claim 10, wherein the word line overlaps the storage node in the vertical direction.

16. A semiconductor memory device comprising:
a first channel layer extending in a second horizontal direction on a substrate and apart in a first horizontal direction perpendicular to the second horizontal direction, the first channel layer having a first surface and a second surface opposite to the first surface in the second horizontal direction;
a second channel layer above and below the first channel layer, the second channel layer having a first surface and a second surface opposite to the first surface in the second horizontal direction;
a storage node disposed above and below the first channel layer and in contact with the first surface of the second channel layer and disposed inwardly relative to the first surface of the first channel layer in the second horizontal direction, wherein the second channel layer and the storage node surround the first channel layer;
a bit line contacting a first end portion of each of the first channel layer and the second channel layer in a vertical direction perpendicular to the first horizontal direction and the second horizontal direction;
a ground electrode in contact with a second end portion of the first channel layer in the vertical direction;
a word line above the second channel layer between the bit line and the ground electrode, wherein the word line surrounds the second channel layer;
a first gate insulating layer between the first channel layer and the storage node and between the first channel layer and the second channel layer; and
a second gate insulating layer between the second channel layer and the word line and between the storage node and the word line.

17. The semiconductor memory device of claim 16, wherein a bit line-side channel doping region is in contact with the bit line at the first end portion of the first channel layer.

18. The semiconductor memory device of claim 17, wherein the bit line-side channel doping region is aligned with a first end portion of the word line in the vertical direction, overlaps the word line, or is recessed away from the first end portion of the word line.

19. The semiconductor memory device of claim 16, wherein a ground-side channel doping region in contact with the ground electrode is at the second end portion of the first channel layer.

20. The semiconductor memory device of claim 19, wherein the ground-side channel doping region is aligned with an end portion of the storage node in the vertical direction, overlaps the storage node in the vertical direction, or is recessed away from the end portion of the storage node.
